(19) United States
(12) Patent Application Publication
(10) Pub. No.: US 2023/0146151 A1
(43) Pub. Date: May 11, 2023

(54) SEMICONDUCTOR DEVICES

(71) Applicant: SAMSUNG ELECTRONICS CO., LTD., Suwon-si (KR)

(72) Inventor: Jongmin LEE, Hwaseong-si (KR)

(21) Appl. No.: 17/944,407

(22) Filed: Sep. 14, 2022

(30) Foreign Application Priority Data
Nov. 10, 2021 (KR) 10-2021-0154156

(51) Int. Cl. H01L 27/108

(52) U.S. Cl. CPC H01L 27/10897; H01L 27/10814; H01L 27/10894

(57) ABSTRACT

A semiconductor device includes gate structures, bit line structures, contact plug structures, first capacitors, and second capacitors. The gate structures are formed in a substrate including a cell region and a peripheral circuit region, and each of the gate structures extends in a first direction. The bit line structures are formed on the cell region of the substrate, and each of the bit line structures extends in a second direction. The contact plug structures are disposed in the second direction between the bit line structures on the substrate. The first capacitors are formed on the contact plug structures, respectively. The conductive pad is formed on the peripheral circuit region of the substrate, and is electrically insulated from the substrate. The second capacitors are formed on the conductive pad, and are disposed in the first and second directions.

### CROSS-REFERENCE TO RELATED APPLICATION

This application claims priority under 35 U.S.C. § 119 to Korean Patent Application No. 10-2021-0154156, filed on Nov. 10, 2021 in the Korean Intellectual Property Office, the disclosure of which is incorporated by reference in its entirety herein.

### TECHNICAL FIELD

Embodiments of the present disclosure relate to a semiconductor device. More particularly, embodiments of the present disclosure relate to a DRAM device.

### DISCUSSION OF RELATED ART

In a DRAM device, cell capacitors may be formed in a cell region, and decoupling capacitors may be formed in a peripheral circuit region. As the integration of a DRAM device increases, each cell capacitor has to have an increasingly small size to enable more cell capacitors to be formed in the cell region. However, an opening for forming the cell capacitor may not have a sufficiently small size by a single process due to a low resolution of an ArF lithography process that uses argon fluoride (ArF) as an exposure light.

Thus, a double patterning process may be performed to form a cell capacitor having a small size. However, a decoupling capacitor that may be formed simultaneously with the cell capacitor may also have a small size, and thus the entire surface of a lower electrode of the decoupling capacitor may not be sufficiently used so that the total electric capacitance may decrease.

### SUMMARY

Embodiments of the present disclosure provide a semiconductor device having increased characteristics.

According to an embodiment of the present disclosure a semiconductor device includes a substrate including a cell region and a peripheral circuit region. Gate structures are on the cell region of the substrate. Each of the gate structures may extend in a first direction substantially parallel to an upper surface of the substrate. Bit line structures may be formed on the cell region of the substrate, and each of the bit line structures may extend in a second direction substantially parallel to the upper surface of the substrate and crossing the first direction. Contact plug structures may be disposed in the second direction between the bit line structures on the substrate. First capacitors may be formed on the contact plug structures, respectively. A conductive pad may be formed on the peripheral circuit region of the substrate, and may be electrically insulated from the substrate. Second capacitors may be formed on the conductive pad, and may be arranged in the first and second directions.

Each of the first capacitors may include a first lower electrode having a first cup shape, a first dielectric pattern on a surface of the first lower electrode and filling an inner space of the first cup shape of the first lower electrode, and a first upper electrode on a surface of the first dielectric pattern. Each of the second capacitors may include a second lower electrode having a second cup shape, a second dielectric pattern on a surface of the second lower electrode, and a second upper electrode on a surface of the second dielectric pattern. The second dielectric pattern and the second upper electrode may fill an inner space of the second cup shape of the second lower electrode.

According to an embodiment of the present disclosure, a semiconductor device includes a substrate including a cell region and a peripheral circuit region. Gate structures are on the cell region of the substrate. Each of the gate structures may extend in a first direction substantially parallel to an upper surface of the substrate in the cell region. Bit line structures may be formed on the cell region of the substrate, and each of the bit line structures may extend in a second direction substantially parallel to the upper surface of the substrate and crossing the first direction. Contact plug structures may be disposed in the second direction between the bit line structures on the substrate. First capacitors may be formed on the contact plug structures, respectively. A conductive pad may be formed on the peripheral circuit region of the substrate, and may be electrically insulated from the substrate. Second capacitors may be formed on the conductive pad, and may be arranged in the first and second directions. Each of the first capacitors may include a first lower electrode having a first cup shape, a first dielectric pattern on a surface of the first lower electrode, a first upper electrode on a surface of the first dielectric pattern, a third upper electrode on a surface of the first upper electrode. Each of the second capacitors may include a second lower electrode having a second cup shape, a second dielectric pattern on a surface of the second lower electrode, a second upper electrode on a surface of the second dielectric pattern, and a fourth upper electrode on a surface of the second upper electrode. The second dielectric pattern, the second upper electrode and the fourth upper electrode may fill an inner space of the second cup shape of the second lower electrode.

According to an embodiment of the present disclosure, a semiconductor device includes a substrate including a cell region and a peripheral circuit region. Gate structures are on the cell region of the substrate. Each of the gate structures may extend in a first direction substantially parallel to an upper surface of the substrate in the cell region. Bit line structures may be formed on the cell region of the substrate, and each of the bit line structures may extend in a second direction substantially parallel to the upper surface of the substrate and crossing the first direction. Contact plug structures may be disposed in the second direction between the bit line structures on the substrate. First capacitors may be formed on the contact plug structures, respectively. A conductive pad may be formed on the peripheral circuit region of the substrate, and may be electrically insulated from the substrate. Second capacitors may be formed on the conductive pad, and may be arranged in the first and second directions. Each of the first capacitors may include a first lower electrode having a pillar shape, a first dielectric pattern on a surface of the first lower electrode, a first upper electrode on a surface of the first dielectric pattern, and a third upper electrode on a surface of the first upper electrode. Each of the second capacitors may include a second lower electrode having a cup shape, a second dielectric pattern on a surface of the second lower electrode, a second upper electrode on a surface of the second dielectric pattern, and a fourth upper electrode on a surface of the second upper electrode. The second dielectric pattern, the second upper electrode and the fourth upper electrode may fill an inner space of the cup shape of the second lower electrode.

In a method of manufacturing the semiconductor device according to an embodiment of the present disclosure, openings having different sizes may be formed on the cell region and the peripheral circuit region, respectively, by an EUV lithography process, and cell capacitors and decoupling capacitors may be formed in the openings on the cell region and the peripheral circuit region, respectively. Thus, the cell capacitors may have high integration and the decoupling capacitors may have increased electric capacitance.

### BRIEF DESCRIPTION OF THE DRAWINGS

FIGS. 1 to 42 are plan views and cross-sectional views illustrating a method of manufacturing a semiconductor device according to embodiments of the present disclosure.

FIGS. 43 and 44 are cross-sectional views illustrating the first and second capacitors in accordance with embodiments of the present disclosure.

### DETAILED DESCRIPTION OF EMBODIMENTS

The above and other aspects and features of a method of cutting a fine pattern, a method of forming active patterns using the same, and a method of manufacturing a semiconductor device using the same in accordance with embodiments of the present disclosure will become readily understood from detail descriptions that follow, with reference to the accompanying drawings. It will be understood that, although the terms “first,” “second,” and/or “third” may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second or third element, component, region, layer or section without departing from the teachings of the present disclosure.

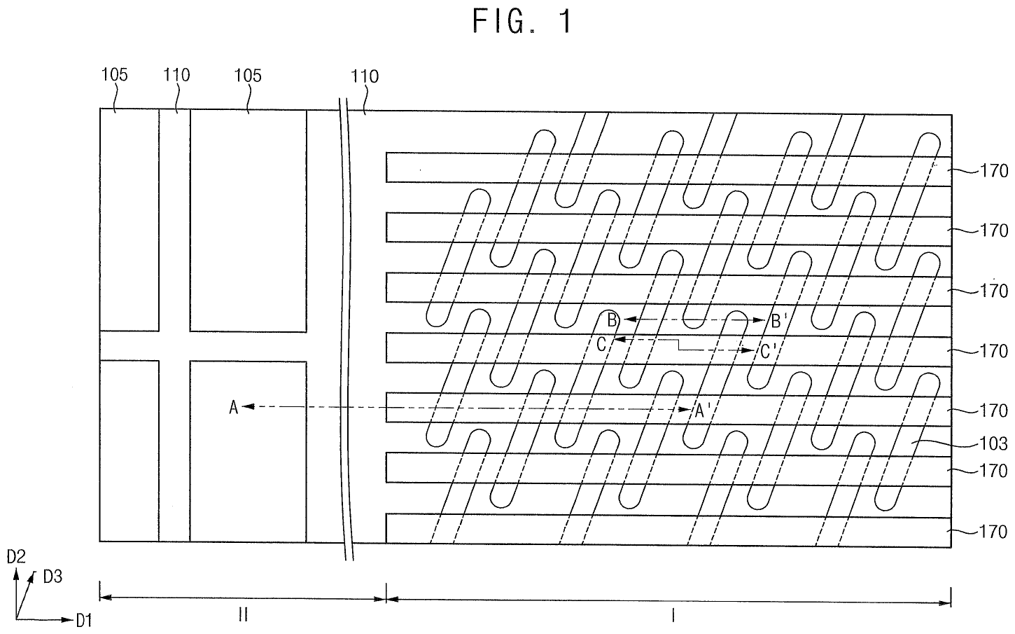

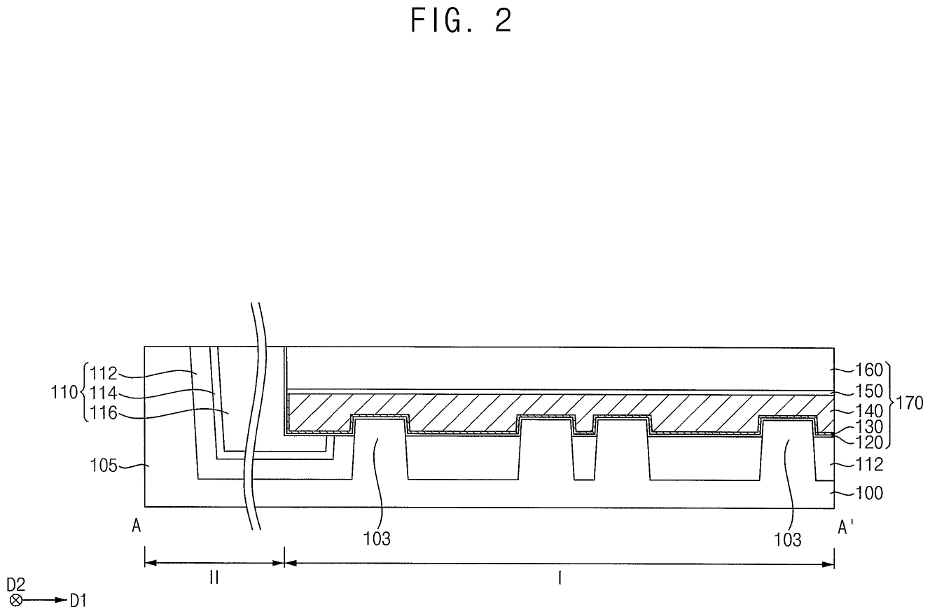

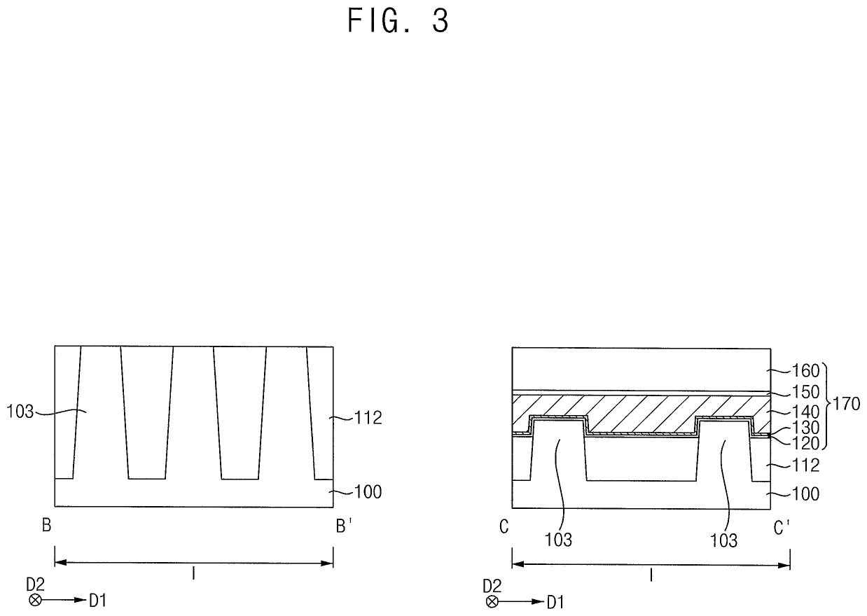

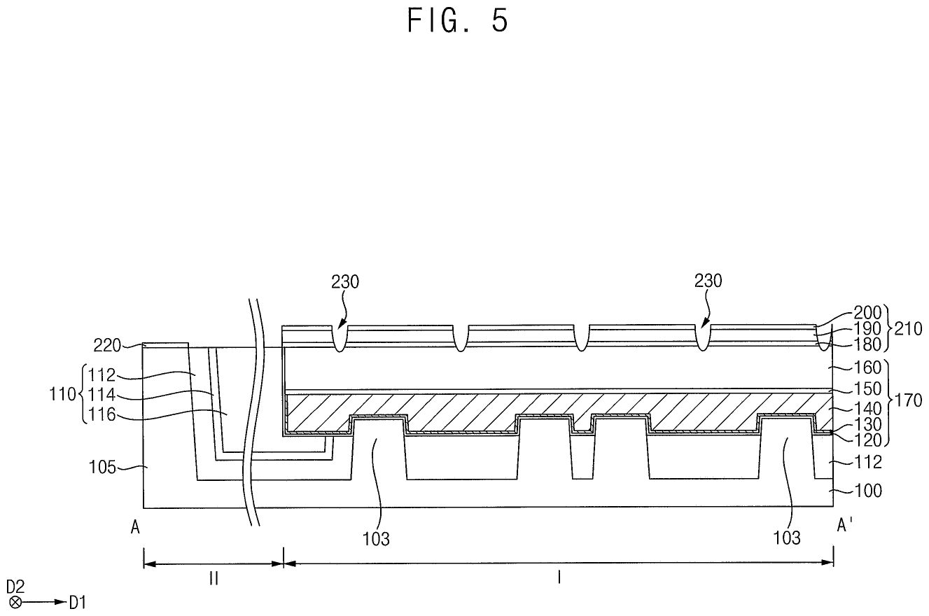

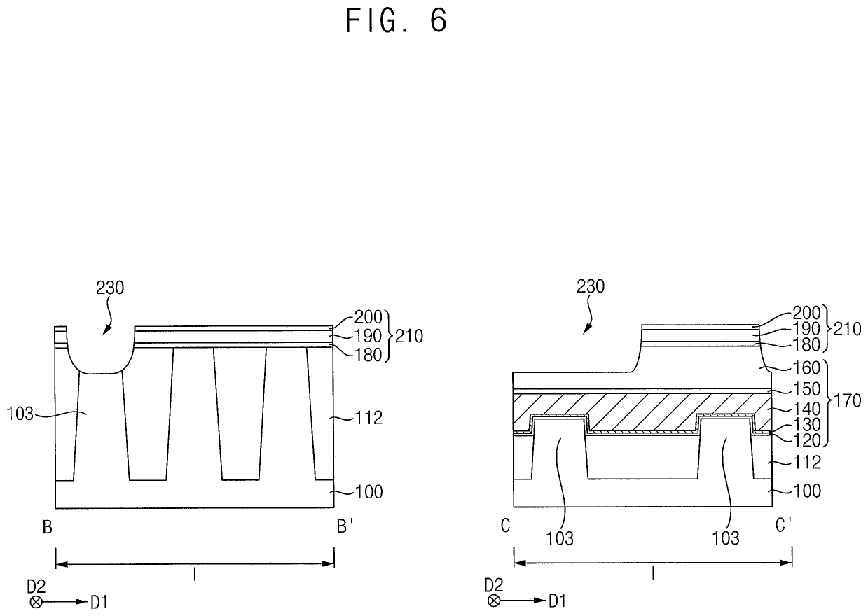

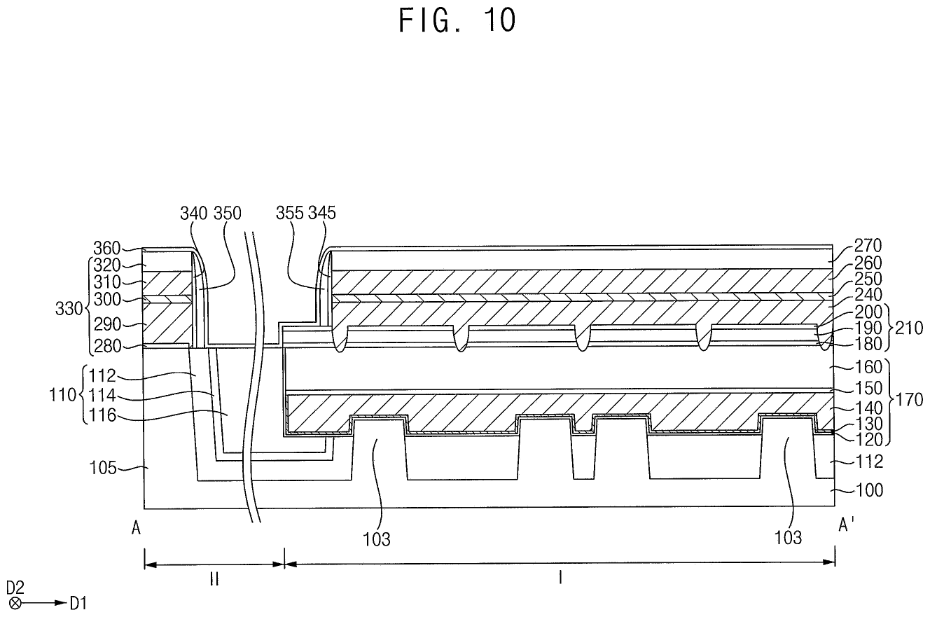

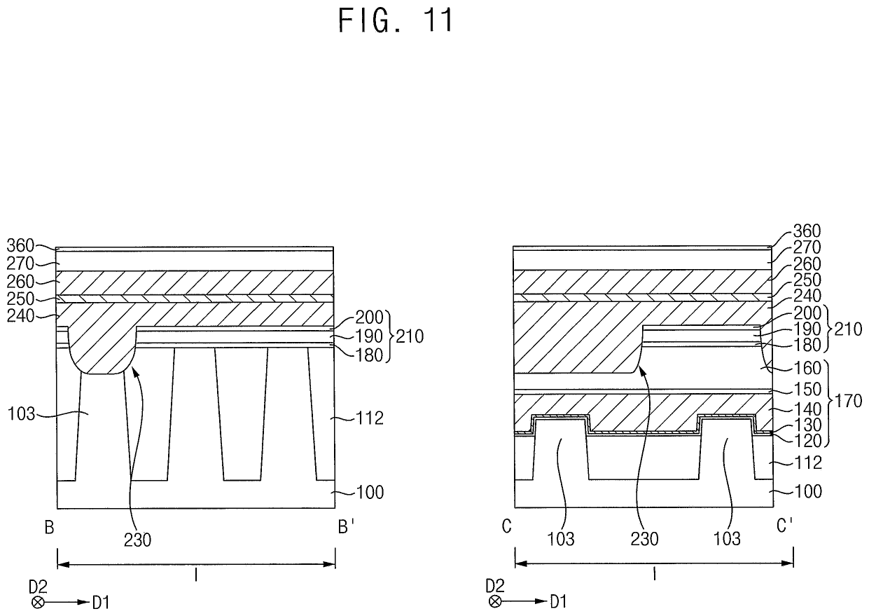

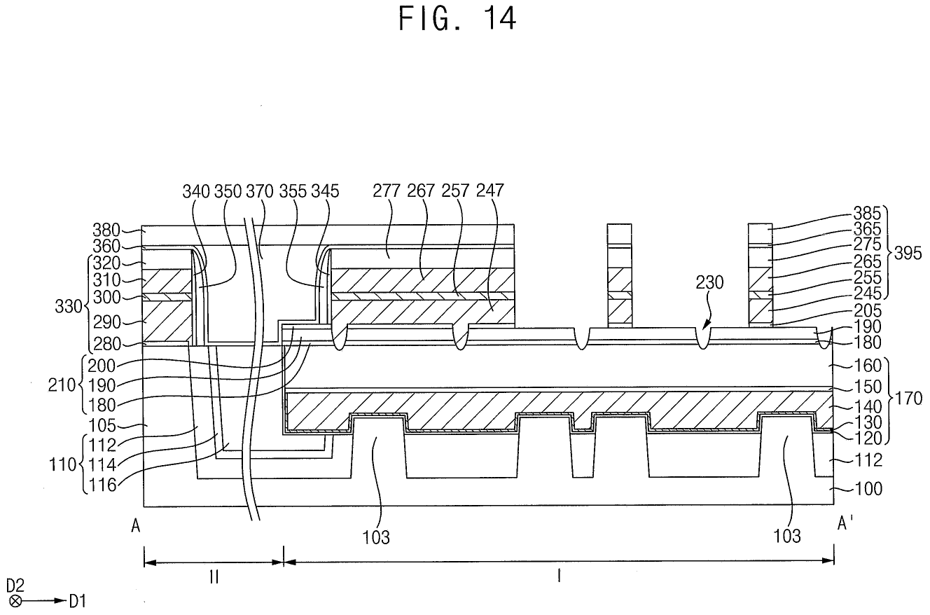

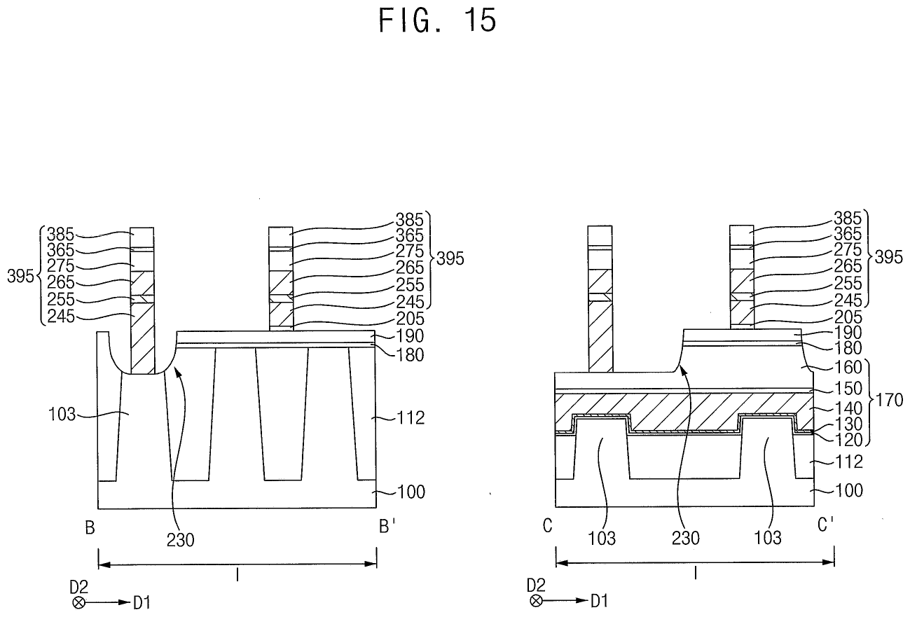

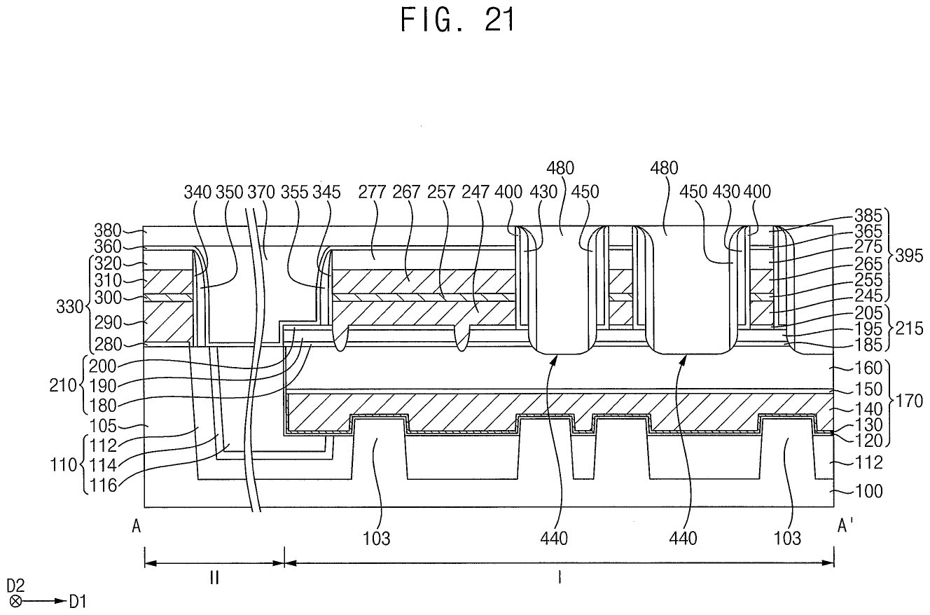

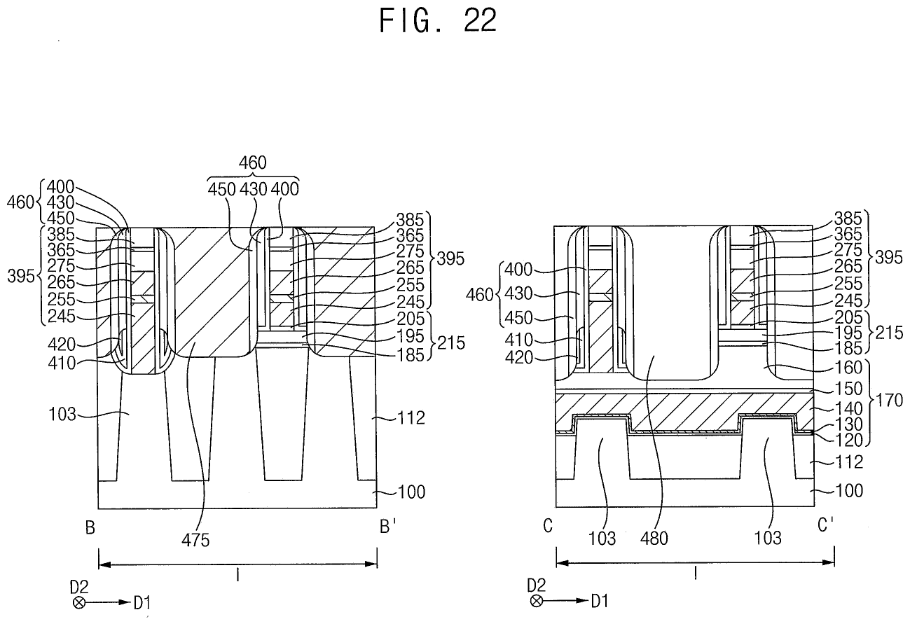

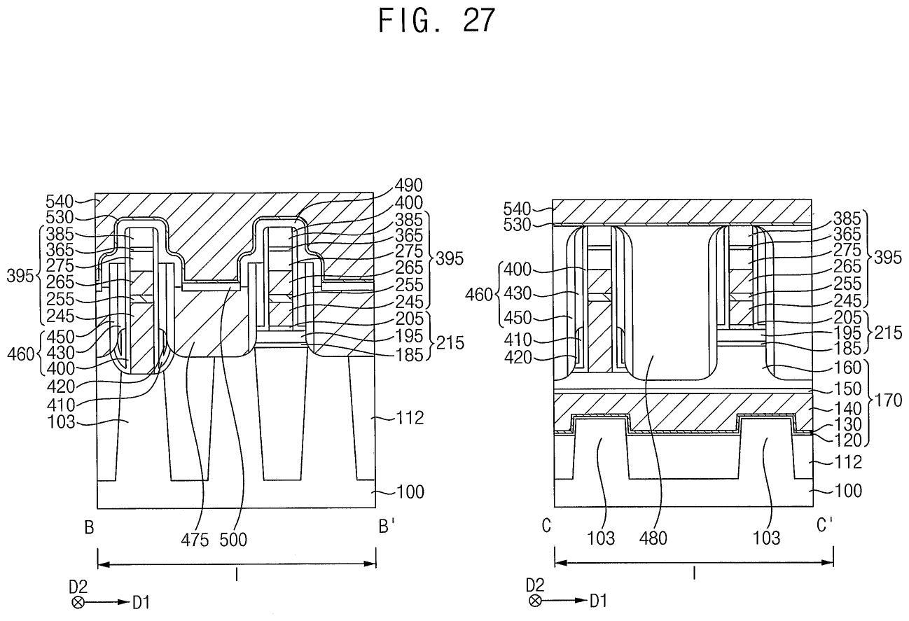

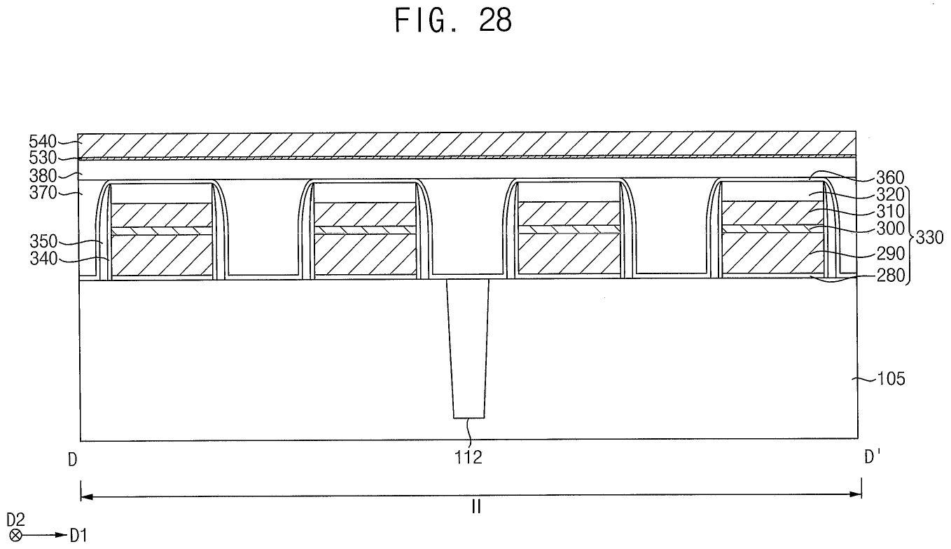

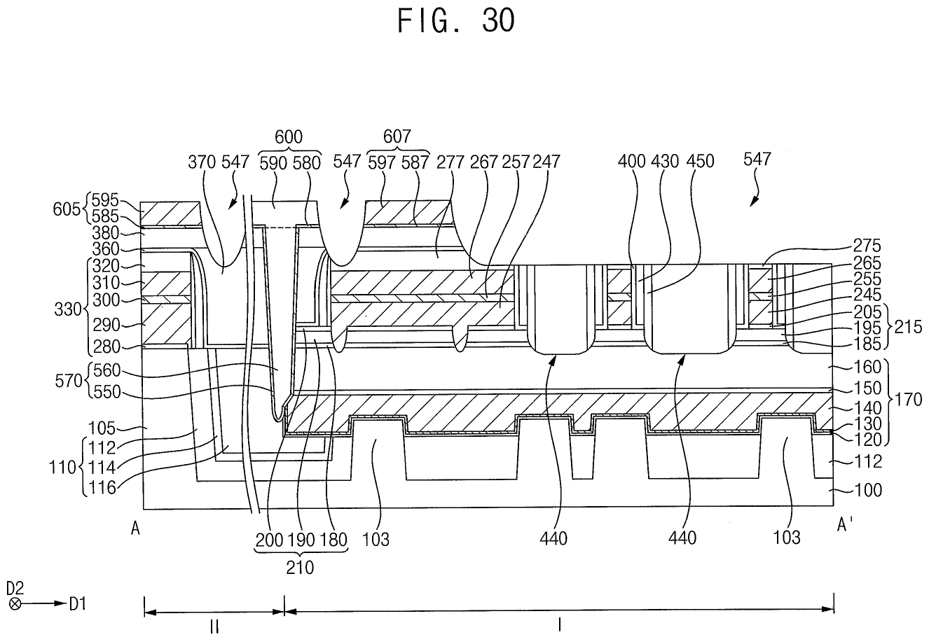

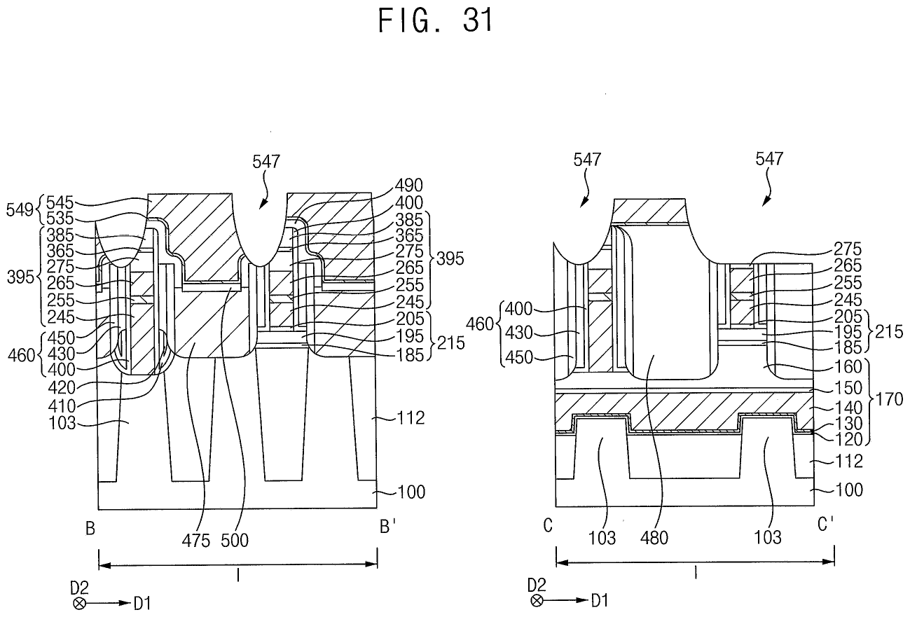

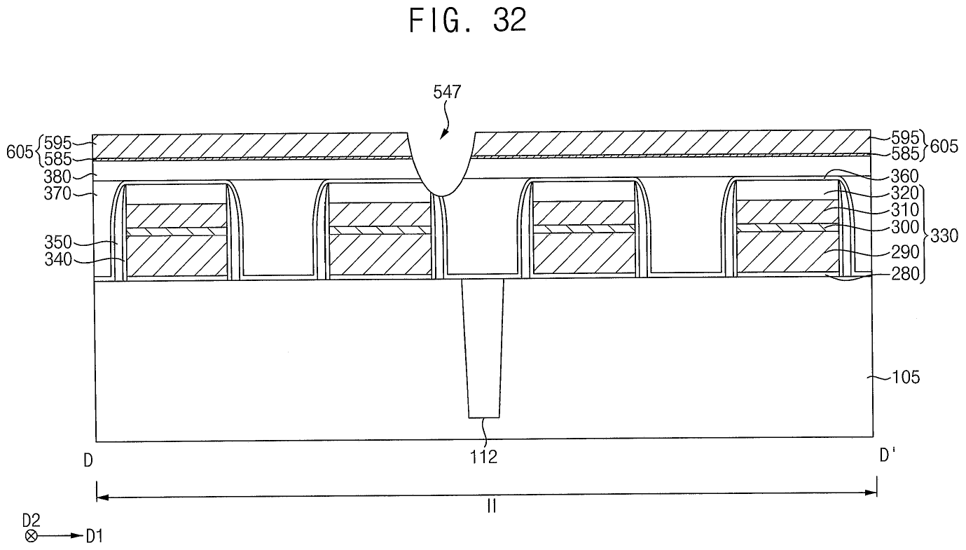

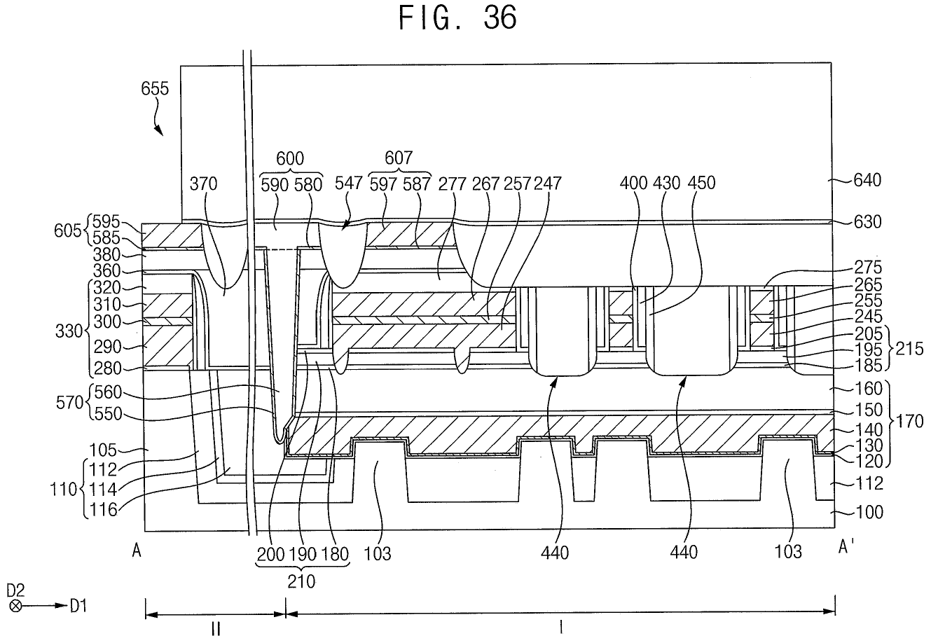

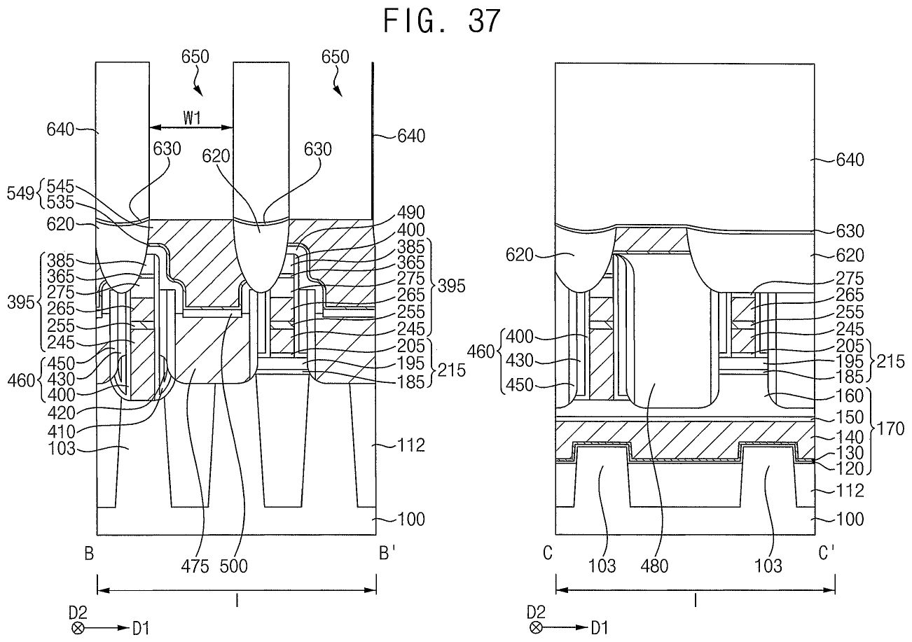

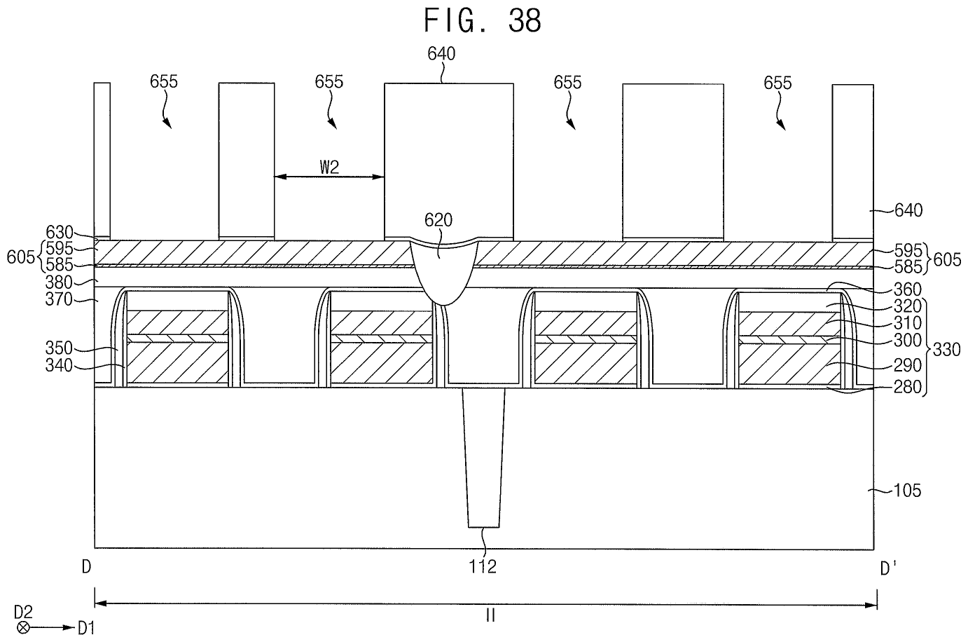

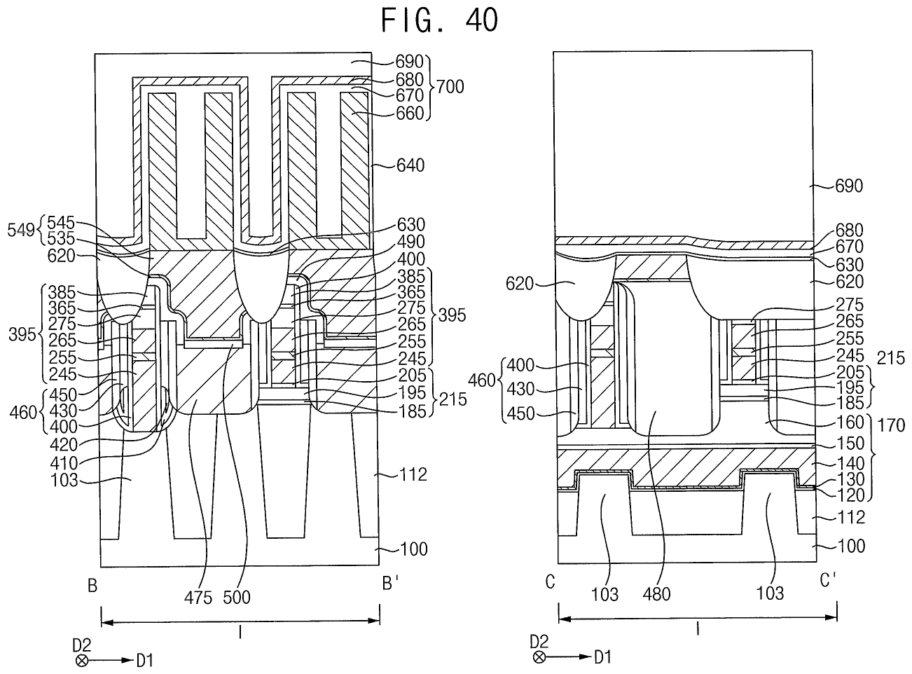

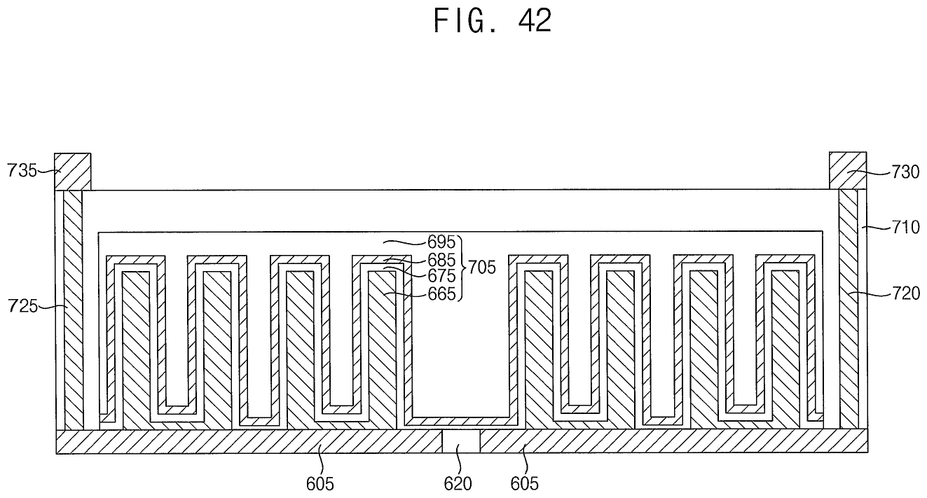

FIGS. 1 to 42 are plan views and cross-sectional views illustrating a method of manufacturing a semiconductor device according to example embodiments. Specifically, FIGS. 1, 4, 9, 13, 20, 24, 29 and 35 are the plan views, FIGS. 2, 5, 7, 10, 12, 14, 16, 18, 21, 25-26, 30, 36 and 39 are cross-sectional views taken along lines A-A′ of corresponding plan views, respectively, each of FIGS. 3, 6, 8, 11, 15, 17, 19, 22-23, 27, 31, 33, 35, 37 and 40 includes cross-sections taken along lines B-B′ and C-C′ of a corresponding plan view, and FIGS. 28, 32, 34, 38 and 41 are cross-sectional views taken along lines D-D′ of corresponding plan views, respectively. FIG. 42 is a cross-sectional view illustrating a method of forming wirings connected to a decoupling capacitor.

Hereinafter, in the specification (and not necessarily in the claims), two directions substantially parallel to an upper surface of a substrate 100 and substantially perpendicular to each other may be referred to as first and second directions D1 and D2, respectively, and a direction substantially parallel to the upper surface of the substrate 100 and having an acute angle with respect to the first and second directions D1 and D2 may be referred to as a third direction D3. However, embodiments of the present disclosure are not necessarily limited thereto. For example, the first and second directions D1, D2 may cross each other at various different angles.

Referring to FIGS. 1 to 3, first and second active patterns 103 and 105 may be formed on the substrate 100 including first and second regions I and II, and an isolation pattern structure 110 may be formed to cover sidewalls of the first and second active patterns 103 and 105, respectively.

In an embodiment, the substrate 100 may include silicon, germanium, silicon-germanium, or a III-V group compound semiconductor, such as GaP, GaAs, or GaSb.

For example, the substrate 100 may be a silicon-on-insulator (SOI) substrate or a germanium-on-insulator (GOI) substrate.

The first region I of the substrate 100 may be a cell region on which memory cells are formed, and the second region II of the substrate 100 surrounding the first region I of the substrate 100 may be a peripheral circuit region on which peripheral circuit patterns for driving the memory cells are formed.

In an embodiment, the first and second active patterns 103 and 105 may be formed by removing an upper portion of the substrate 100 to form a first recess. The first active pattern 103 may extend in the third direction D3 in the first region I of the substrate 100, and a plurality of first active patterns 103 may be spaced apart from each other in each of the first, second and/or third directions D1, D2 and/or D3. Additionally, a plurality of second active patterns 105 may be spaced apart from each other in each of the first and second directions D1 and D2, and FIG. 1 shows some of the second active patterns 105. However, the number of the plurality of first active patterns 103 and second active patterns 105 is not limited to that shown in FIG. 1.

The isolation pattern structure 110 may include first to third isolation patterns 112, 114 and 116 sequentially stacked on an inner wall of the first recess. A portion of the first recess in the first region I of the substrate 100 may have a relatively small width, and thus only the first isolation pattern 112 may be formed in the portion of the first recess. However, a portion of the first recess in the second region II and/or between the first and second regions I and II of the substrate 100 may have a relatively large width, and thus the first to third isolation patterns 112, 114 and 116 may be formed in such portion of the first recess.

In an embodiment, the first and third isolation patterns 112 and 116 may have an oxide, such as silicon oxide or the like, and the second isolation pattern 114 may include a nitride, such as silicon nitride or the like.

The first active pattern 103 and the isolation pattern structure 110 in the first region I of the substrate 100 may be partially removed to form a second recess extending in the first direction D1.

A first gate structure 170 may be formed in the second recess. The first gate structure 170 may include a first gate insulation pattern 120 on a bottom and a sidewall of the second recess, a first barrier pattern 130 on a portion of the first gate insulation pattern 120 on the bottom and a lower sidewall of the second recess, a first conductive pattern 140 on the first barrier pattern 130 and filling a lower portion of the second recess, a second conductive pattern 150 on the first barrier pattern 130 and the first conductive pattern 140, and a first gate mask 160 on an upper surface of the second conductive pattern 150 and an upper inner sidewall of the first gate insulation pattern 120 and filling an upper portion of the second recess. The first barrier pattern 130, the first conductive pattern 140 and the second conductive pattern 150 may form a first gate electrode.

In an embodiment, the first gate insulation pattern 120 may include an oxide, such as silicon oxide or the like, the first barrier pattern 130 may include a metal nitride, such as titanium nitride, tantalum nitride, etc., the first conductive pattern 140 may include a metal, a metal nitride, a metal silicide, doped polysilicon, etc., the second conductive pattern 150 may include doped polysilicon, and the first gate mask 160 may include a nitride, such as silicon nitride or the like.

Alternatively, the first gate structure 170 may not include the first barrier pattern 130, but may include the first gate insulation pattern 120, the first conductive pattern 140, the second conductive pattern 150 and the first gate mask 160. In this embodiment, the first conductive pattern 140 may include a metal nitride, such as titanium nitride or the like.

In an embodiment, the first gate structure 170 may extend in the first direction D1 on the first region I of the substrate 100, and a plurality of first gate structures 170 may be spaced apart from each other in the second direction D2. As shown in an embodiment of FIG. 1, end portions in the first direction D1 of the first gate structures 170 may be aligned with each other in the second direction D2.

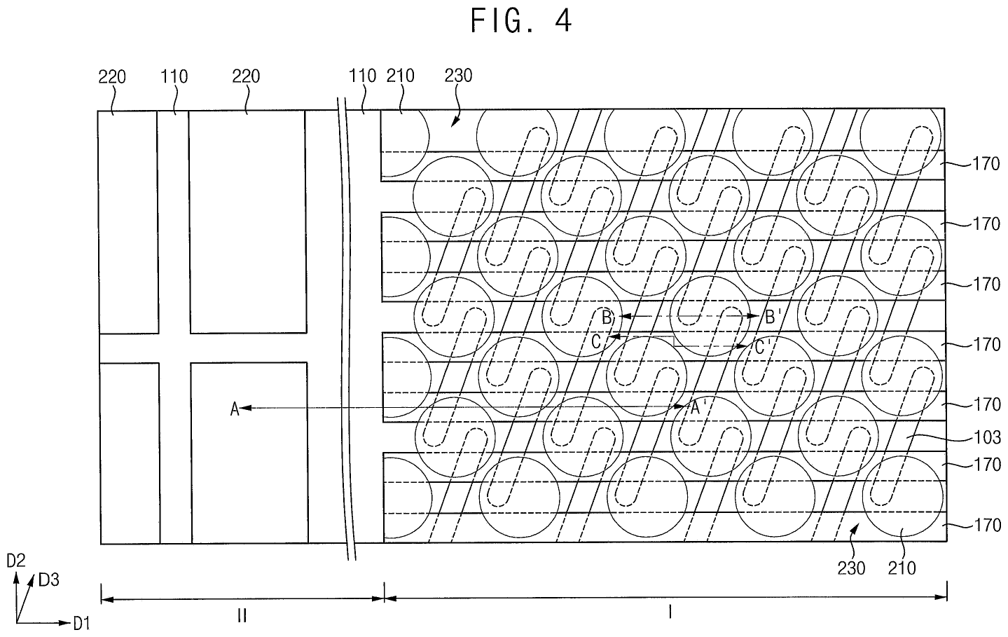

Referring to FIGS. 4 to 6, an insulation layer structure 210 may be formed on the first and second regions I and II of the substrate 100, a portion of the insulation layer structure 210 on the second region II of the substrate 100 may be removed, and, for example, a thermal oxidation process may be performed on the second active pattern 105 on the second region H of the substrate 100 to form a second gate insulation layer 220.

The insulation layer structure 210 may include first to third insulation layers 180, 190 and 200 sequentially stacked. The first and third insulation layers 180 and 200 may include an oxide, such as silicon oxide or the like, and the second insulation layer 190 may include a nitride, such as silicon nitride or the like.

Alternatively, the second and third insulation layers 190 and 200 on the second region II of the substrate 100 among the insulation layer structure 210 may be removed, and the first insulation layer 180 remaining on the second region II of the substrate 100 may serve as a second gate insulation layer 220. In this embodiment, the second gate insulation layer 220 may be formed not only on the second active pattern 105 but also on the isolation pattern structure 110 on the second region II of the substrate 100.

The insulation layer structure 210 may be patterned, and the first active pattern 103, the isolation pattern structure 110, and the first gate mask 160 of the first gate structure 170 may be partially etched using the patterned insulation layer structure 210 as an etching mask to form a first opening 230. In an embodiment, the patterned insulation layer structure 210 may have a shape of a circle or an ellipse in a plan view (e.g., in a plane defined in the first and second directions D1, D2), and a plurality of insulation layer structures 210 may be spaced apart from each other in the first and second directions D1 and D2 on the first region I of the substrate 100. However, embodiments of the present disclosure are not necessarily limited thereto. Each of the insulation layer structures 210 may overlap opposite end portions in the third direction D3 of the first active patterns 103 in a vertical direction substantially perpendicular to the upper surface of the substrate 100.

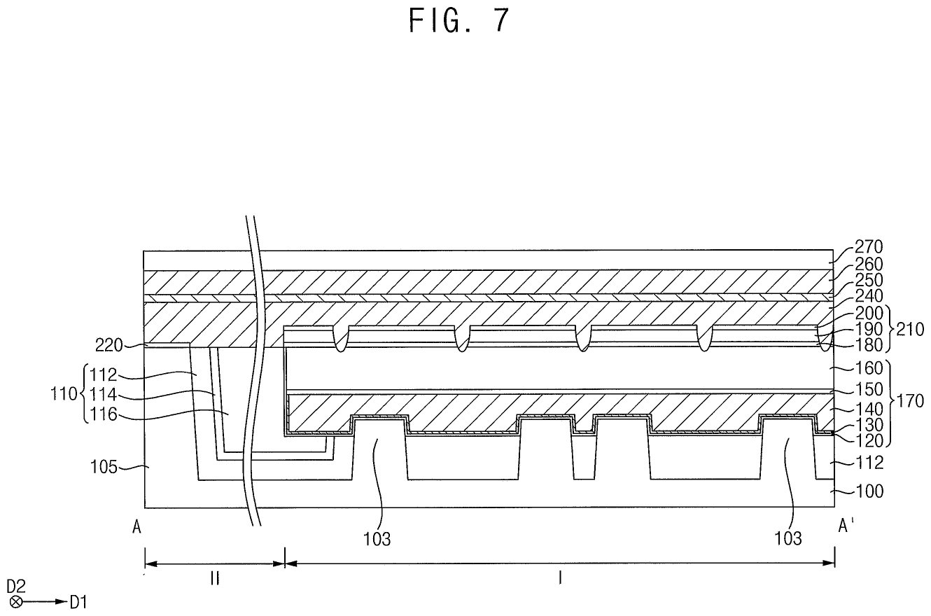

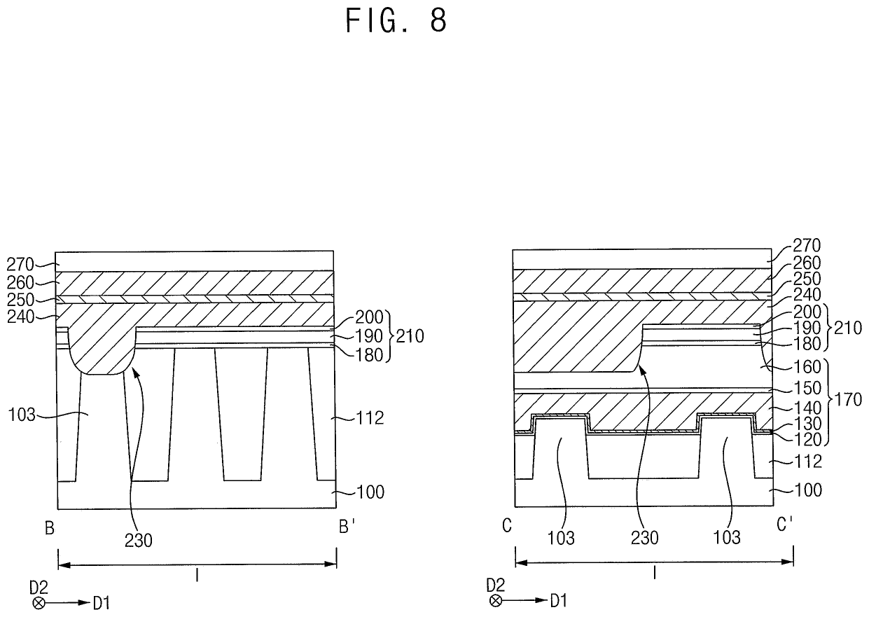

Referring to FIGS. 7 and 8, a third conductive layer 240, a second barrier layer 250, a fourth conductive layer 260 and a first mask layer 270 may be sequentially stacked on the insulation layer structure 210, the first active pattern 103 exposed by the first opening 230, the isolation pattern structure 110 and the first gate structure 170 on the first region I of the substrate 100, and the second gate insulation layer 220 and the isolation pattern structure 110 on the second region II of the substrate 100, which may form a conductive structure layer. The third conductive layer 240 may fill the first opening 230.

In an embodiment, the third conductive layer 240 may include doped polysilicon, the second barrier layer 250 may include a metal silicon nitride, such as titanium silicon nitride, the fourth conductive layer 260 may include a metal, such as tungsten, and the first mask layer 270 may include a nitride, such as silicon nitride. However, embodiments of the present disclosure are not necessarily limited thereto.

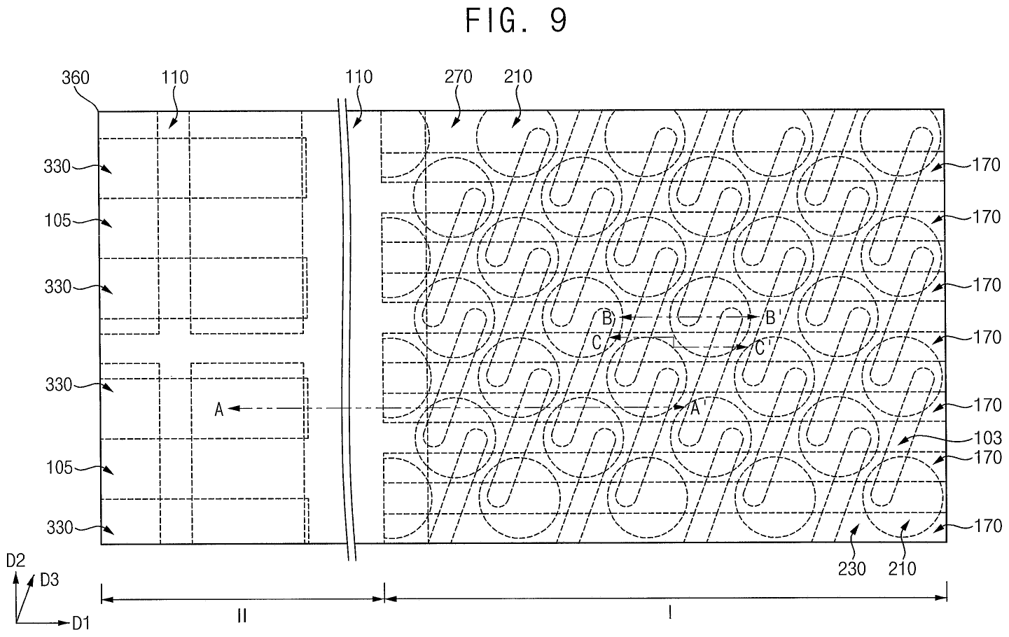

Referring to FIGS. 9 to 11, the conductive structure layer and the second gate insulation layer 220 may be patterned to form a second gate structure 330 on the second region II of the substrate 100.

The second gate structure 330 may include a second gate insulation pattern 280, a third conductive pattern 290, a second barrier pattern 300, a fourth conductive pattern 310 and a second gate mask 320 sequentially stacked in a vertical direction substantially perpendicular to an upper surface of the substrate 100, and the third conductive pattern 290, the second barrier pattern 300 and the fourth conductive pattern 310 may form a second gate electrode.

The second gate structure 330 may partially overlap the second active pattern 105 in the vertical direction on the second region II of the substrate 100. FIG. 9 shows an embodiment including 4 second gate structures 330, each of which may extend in the first direction D1 and are spaced apart from each other in the second direction D2. However, embodiments of the present disclosure are not necessarily limited thereto.

In an embodiment, a portion of the conductive structure layer on an edge portion of the first region I of the substrate 100 adjacent to the second region II of the substrate 100 may also be removed, and thus the insulation layer structure 210, and upper surfaces of the first active pattern 103, the isolation pattern structure 110 and the first gate structure 170 exposed by the first opening 230 may also be partially exposed.

A first spacer structure may be formed on a sidewall of the second gate structure 330, and a second spacer structure may be formed on a sidewall of the conductive structure layer remaining on the first region I of the substrate 100. The first spacer structure may include first and third spacers 340 and 350 stacked on the sidewall of the second gate structure 330 in a horizontal direction substantially parallel to the upper surface of the substrate 100 (e.g., the first direction D1), and the second spacer structure may include second and fourth spacers 345 and 355 stacked on the sidewall of the conductive structure layer in the horizontal direction.

The first and second spacers 340 and 345 may be formed by forming a first spacer layer on the substrate 100 to cover the conductive structure layer and the second gate structure 330 and anisotropically etching the first spacer layer. The second and third spacers 345 and 350 may be formed by forming a second spacer layer on the substrate 100 to cover the conductive structure layer, the second gate structure 330 and the first and second spacers 340 and 345 and anisotropically etching the second spacer layer.

In an embodiment, the first and second spacers 340 and 345 may include a nitride, such as silicon nitride or the like, and the third and fourth spacers 350 and 355 may include an oxide, such as silicon oxide or the like.

However, the structure of the first and second spacer structures may not necessarily be limited thereto, and each of the first and second spacer structures may include a single spacer or more than two spacers sequentially stacked.

In an embodiment, impurities may be implanted into upper portions of the second active pattern 105 adjacent to the second gate structure 330 to form source/drain layers, and the second gate structure 330 and the source/drain layers may form a transistor. However, impurities may not be implanted into an upper portion of the second active pattern 105 adjacent to one or more of the second gate structures 330, which may be a dummy gate structure not serving as a gate of a transistor.

A first etch stop layer 360 may be formed on the substrate 100 to cover the conductive structure layer, the second gate structure 330, the first and second spacer structures, and the isolation pattern structure 110. In an embodiment, the first etch stop layer 360 may include a nitride, such as silicon nitride or the like.

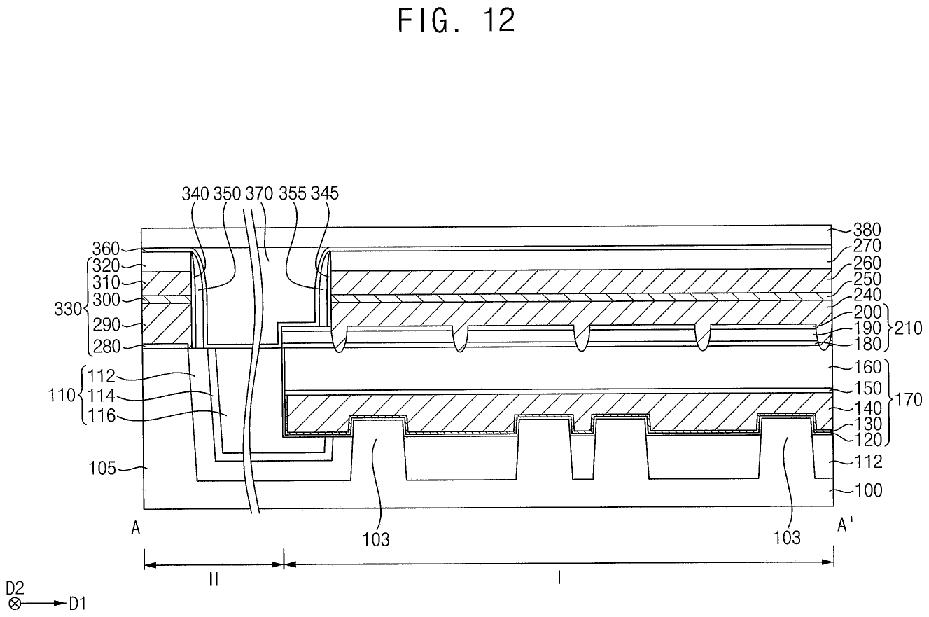

Referring to FIG. 12, a first insulating interlayer 370 may be formed on the first etch stop layer 360 to a sufficient height, and may be planarized until an upper surface of the second gate structure 330 and an upper surface of a portion of the first etch stop layer 360 on the conductive structure layer are exposed.

Thus, the first insulating interlayer 370 may fill a space between the first spacer structures on the sidewall of the second gate structures 330, and a space between the first spacer structure on the sidewall of the second gate structure 330 and the second spacer structure on the sidewall of the conductive structure layer. A first capping layer 380 may then be disposed on the etch stop layer 360 and the first insulating interlayer 370.

In an embodiment, the first insulating interlayer 370 may include an oxide, such as silicon oxide or the like, and the first capping layer 380 may include a nitride, such as silicon nitride or the like.

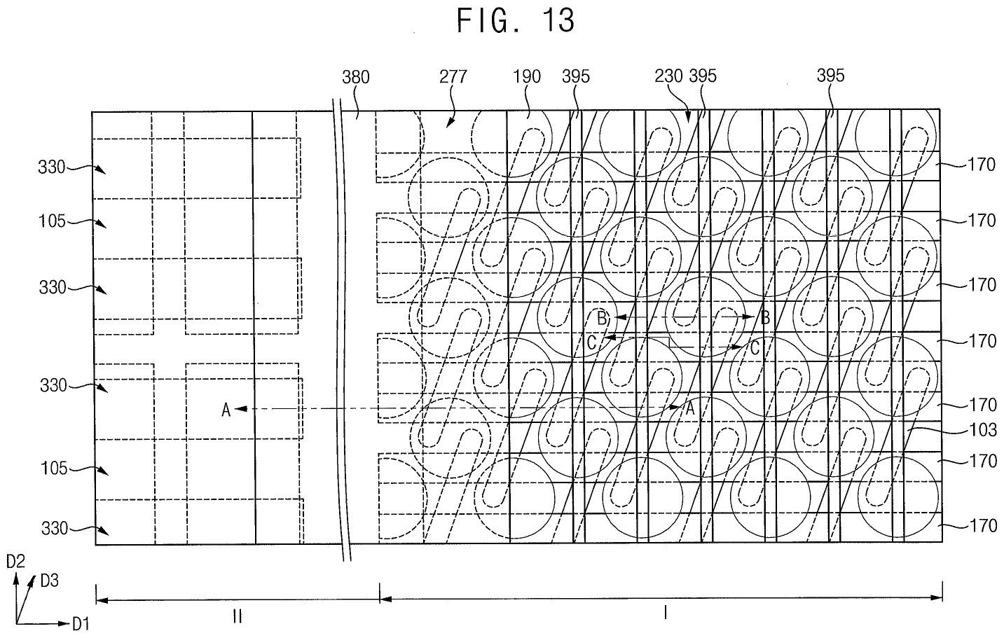

Referring to FIGS. 13 to 15, a portion of the first capping layer 380 on the first region I of the substrate 100 may be etched to form a first capping pattern 385, and the first etch stop layer 360, the first mask layer 270, the fourth conductive layer 260, the second barrier layer 250 and the third conductive layer 240 may be sequentially etched using the first capping pattern 385 as an etching mask.

In an embodiment, the first capping pattern 385 may extend in the second direction D2 on the first region I of the substrate 100, and a plurality of first capping patterns 385 may be formed to be spaced apart from each other in the first direction D1. The first capping layer 380 may remain on the second region II of the substrate 100.

By the etching process, on the first region I of the substrate 100, a fifth conductive pattern 245, a third barrier pattern 255, a sixth conductive pattern 265, a first mask 275, a first etch stop pattern 365 and the first capping pattern 385 may be sequentially stacked on the first opening 230, and a third insulation pattern 205, the fifth conductive pattern 245, the third barrier pattern 255, the sixth conductive pattern 265, the first mask 275, the first etch stop pattern 365 and the first capping pattern 385 may be sequentially stacked on the second insulation layer 190 of the insulation layer structure 210 at a position outside of the first opening 230 (e.g., in the first direction D1).

Hereinafter, the fifth conductive pattern 245, the third barrier pattern 255, the sixth conductive pattern 265, the first mask 275, the first etch stop pattern 365 and the first capping pattern 385 sequentially stacked may be referred to as a bit line structure 395. In an embodiment, the bit line structure 395 may extend in the second direction D2 on the first region I of the substrate 100, and a plurality of bit line structures 395 may be spaced apart from each other in the first direction D1. In an embodiment, the bit line structures 395 may contact central upper surfaces (e.g., in the third direction D3) of corresponding ones of the first active patterns 103.

A dummy bit line structure including a seventh conductive pattern 247, a fourth barrier pattern 257, an eighth conductive pattern 267 and a second mask 277 sequentially stacked and extending in the second direction D2 may be formed on a portion of the first region I of the substrate 100 adjacent to the second region II of the substrate 100 in the first direction D1, and the first etch stop layer 360 may remain on the second gate structure 330, the dummy bit line structure, the first and second spacer structures, a portion of the insulation layer structure 210, and the isolation pattern structure 110. Additionally, the first capping layer 380 may remain on portions of the first etch stop layer 360 on upper surfaces of the second gate structure 330 and the dummy bit line structure and the first insulating interlayer 370.

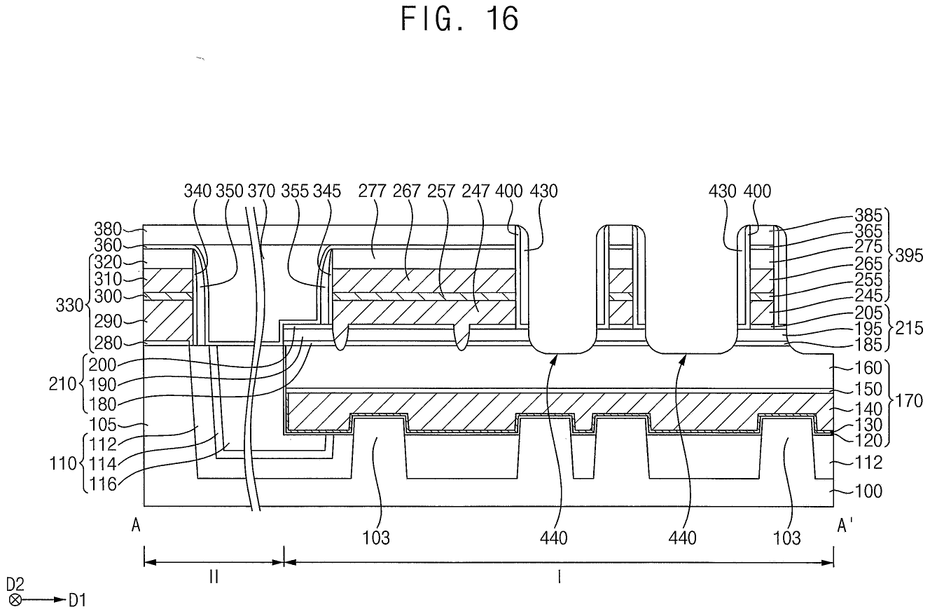

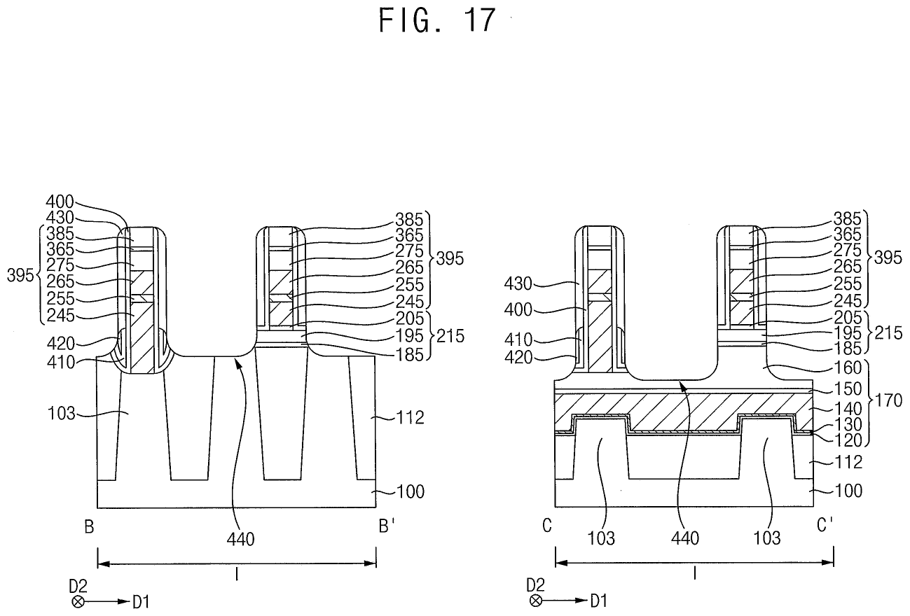

Referring to FIGS. 16 and 17, a fifth spacer layer may be formed on the substrate 100 to cover sidewalls of the bit line structure 395, the dummy bit line structure and the first capping layer 380, and fourth and fifth insulation layers may be sequentially formed on the fifth spacer layer.

The fifth spacer layer may also cover a sidewall of the third insulation pattern 205 between the second insulation layer 190 and the bit line structure 395, and the fifth insulation layer may fill the first opening 230.

In an embodiment, the fifth spacer layer may include a nitride, such as silicon nitride or the like, the fourth insulation layer may include an oxide, such as silicon oxide or the like, and the fifth insulation layer may include a nitride, such as silicon nitride or the like.

The fourth and fifth insulation layers may be etched by an etching process. In an embodiment, the etching process may be performed by a wet etch process using an etching solution including phosphorous acid (H₃PO₄), SCI, hydrogen fluoride (HF), and other portions of the fourth and fifth insulation layers except for a portion in the first opening 230 may be removed. Thus, most of an entire surface of the fifth spacer layer, such as an entire surface except for a portion thereof in the first opening 230 may be exposed, and portions of the fourth and fifth insulation layers remaining in the first opening 230 may form fourth and fifth insulation patterns 410 and 420, respectively.

A sixth spacer layer may be formed on the exposed surface of the fifth spacer layer and the fourth and fifth insulation patterns 410 and 420 in the first opening 230, and may be anisotropically etched to form a sixth spacer 430 on the surface of the fifth spacer layer and the fourth and fifth insulation patterns 410 and 420 to cover a sidewall of the bit line structure 395. The sixth spacer layer may also be formed on a sidewall of the dummy bit line structure. In an embodiment, the sixth spacer layer may include an oxide, such as silicon oxide or the like.

A dry etching process may be performed using the first capping pattern 385 and the sixth spacer 430 as an etching mask to form a second opening 440 exposing the upper surface of the first active pattern 103. An upper surface of the first isolation pattern 112 of the isolation pattern structure 110 and an upper surface of the first gate mask 160 may also be exposed by the second opening 440.

By the dry etching process, portions of the fifth spacer layer on upper surfaces of the first capping pattern 385, the second insulation layer 190 and the first capping layer may be removed, and thus a fifth spacer 400 covering the sidewall of the bit line structure 395 may be formed. The fifth spacer 400 may also cover the sidewall of the dummy bit line structure.

Additionally, during the dry etching process, the first and second insulation layers 180 and 190 may be partially removed, such that first and second insulation patterns 185 and 195 may remain under the bit line structure 395. The first to third insulation patterns 185, 195 and 205 that are sequentially stacked under the bit line structure 395 may form an insulation pattern structure 215.

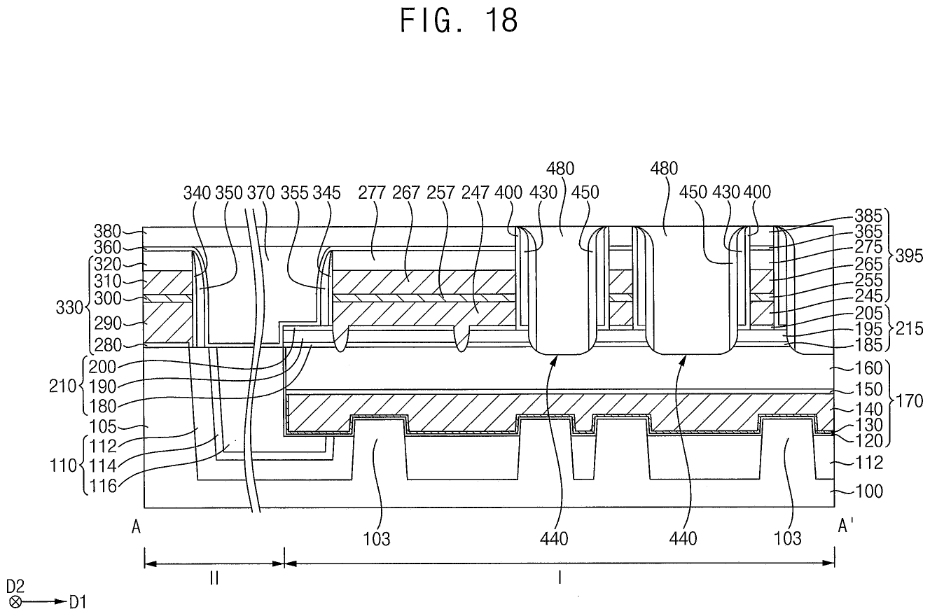

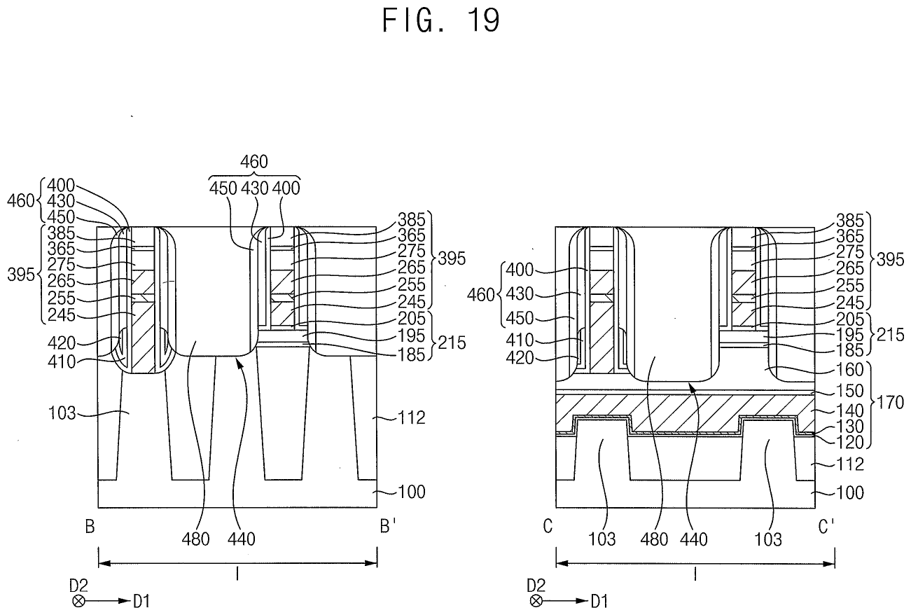

Referring to FIGS. 18 and 19, a seventh spacer layer may be formed on the upper surface of the first capping pattern 385, the upper surface of the first capping layer 380, an outer sidewall of the sixth spacer 430, portions of upper surfaces of the fourth and fifth insulation patterns 410 and 420, and the upper surfaces of the first active pattern 103, the first isolation pattern 112 and the first gate mask 160 exposed by the second opening 440, and may be anisotropically etched to form a seventh spacer 450 covering the sidewall of the bit line structure 395. In an embodiment, the seventh spacer layer may include a nitride, such as silicon nitride or the like.

The fifth to seventh spacers 400, 430 and 450 sequentially stacked in the horizontal direction from the sidewall of the bit line structure 395 on the first region I of the substrate 100 may be referred to as a third spacer structure 460.

A lower contact plug layer may be formed on the first region I of the substrate 100 to fill the second opening 440, and may be planarized until the upper surfaces of the first capping pattern 385 and the first capping layer 380 are exposed.

In an embodiment, the lower contact plug layer may extend in the second direction D2, and a plurality of lower contact plug layers may be spaced apart from each other in the first direction D1 by the bit line structures 395. In an embodiment, the lower contact plug layer may include, doped polysilicon or the like.

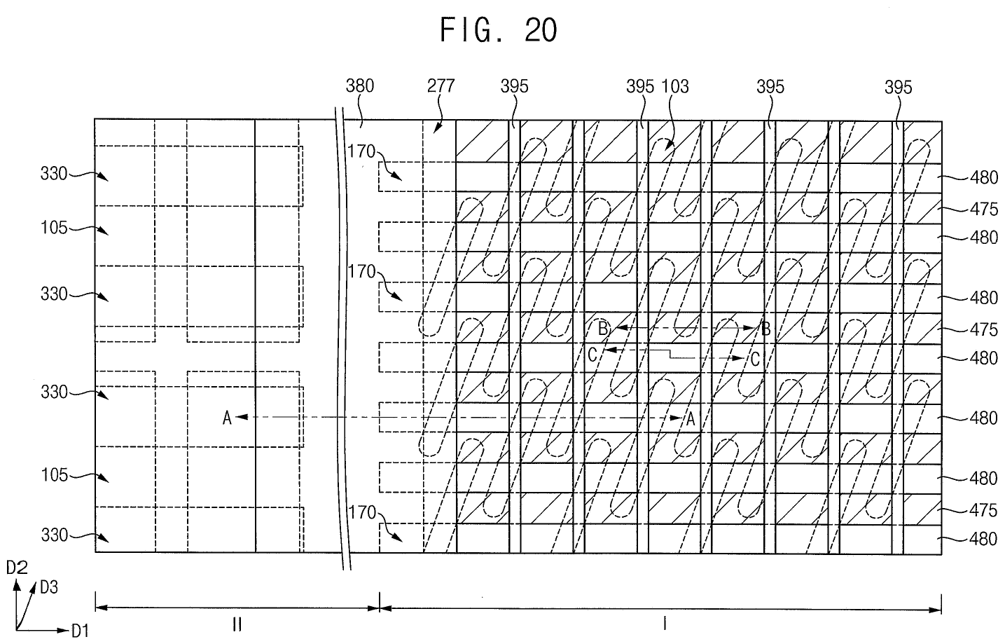

Referring to FIGS. 20 to 22, a third mask having third openings, each of which may extend in the first direction D1 on the first region I of the substrate 100, spaced apart from each other in the second direction D2 may be formed on the first capping pattern 385, the first capping layer 380 and the lower contact plug layer, and an etching process may be performed on the lower contact plug layer using the third mask as an etching mask.

In an embodiment, each of the third openings may overlap the first gate structure 170 on the first region I of the substrate 100 in the vertical direction. As the etching process is performed, a fourth opening may be formed to expose an upper surface of the first gate mask 160 of the first gate structure 170 between the bit line structures 395 on the first region I of the substrate 100.

After removing the third mask, a second capping pattern 480 may be formed on the first region I of the substrate 100 to fill the fourth opening. In an embodiment, the second capping pattern 480 may include a nitride, such as silicon nitride or the like. In an embodiment, the second capping pattern 480 may extend in the first direction D1 between the bit line structures 395, and a plurality of second capping patterns 480 may be spaced apart from each other in the second direction D2.

Thus, the lower contact plug layer 470 extending in the second direction D2 between the bit line structures 395 on the first region I of the substrate 100 may be divided into a plurality of lower contact plugs 475 spaced apart from each other in the second direction D2 by the second capping patterns 480.

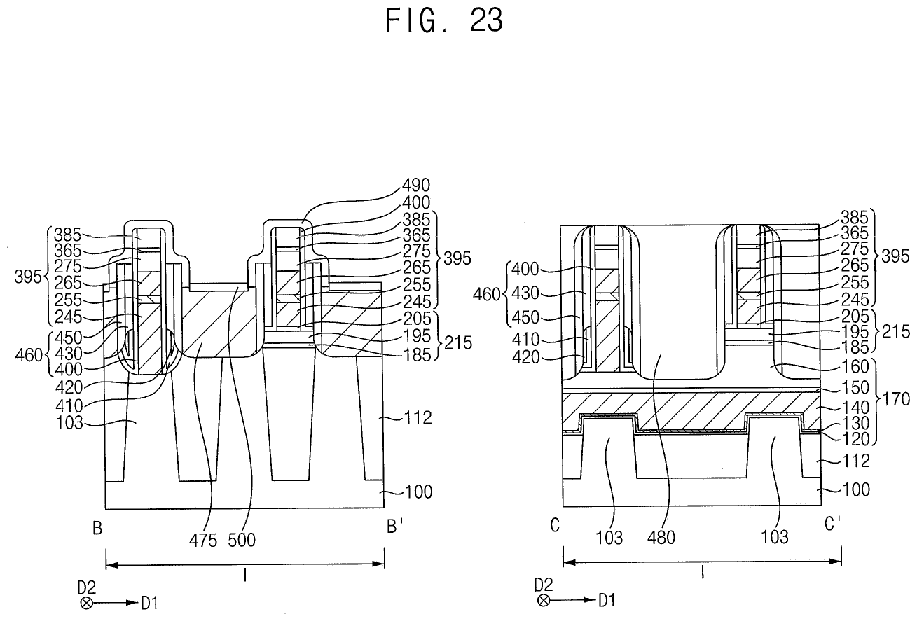

Referring to FIG. 23, an upper portion of the lower contact plug 475 may be removed to expose an upper portion of the third spacer structure 460 on the sidewall of the bit line structure 395, and upper portions of the sixth and seventh spacers 430 and 450 of the exposed third spacer structure 460 may be removed.

An etch back process may be further performed to remove an upper portion of the lower contact plug 475. Thus, an upper surface of the lower contact plug 475 may be lower than uppermost surfaces of the sixth and seventh spacers 430 and 450.

An eighth spacer layer may be formed on the bit line structure 395, the third spacer structure 460, the second capping pattern 480, the first capping layer 380, and the lower contact plug 475, and may be anisotropically etched so that an eighth spacer 490 may be formed to cover the third spacer structure 460 on each of opposite sidewalls of the bit line structure 395 in the first direction D1 and an upper surface of the lower contact plug 475 may not be covered by the eighth spacer 490 but may be exposed.

A metal silicide pattern 500 may be formed on the exposed upper surface of the lower contact plug 475. In an embodiment, the metal silicide patterns 500 may be formed by forming a metal layer on the first and second capping patterns 385 and 480, the first capping layer 380, the eighth spacer 490, and the lower contact plug 475, thermally treating the metal layer, and removing an unreacted portion of the metal layer. In an embodiment, the metal silicide patterns 500 may include cobalt silicide, nickel silicide, titanium silicide, etc.

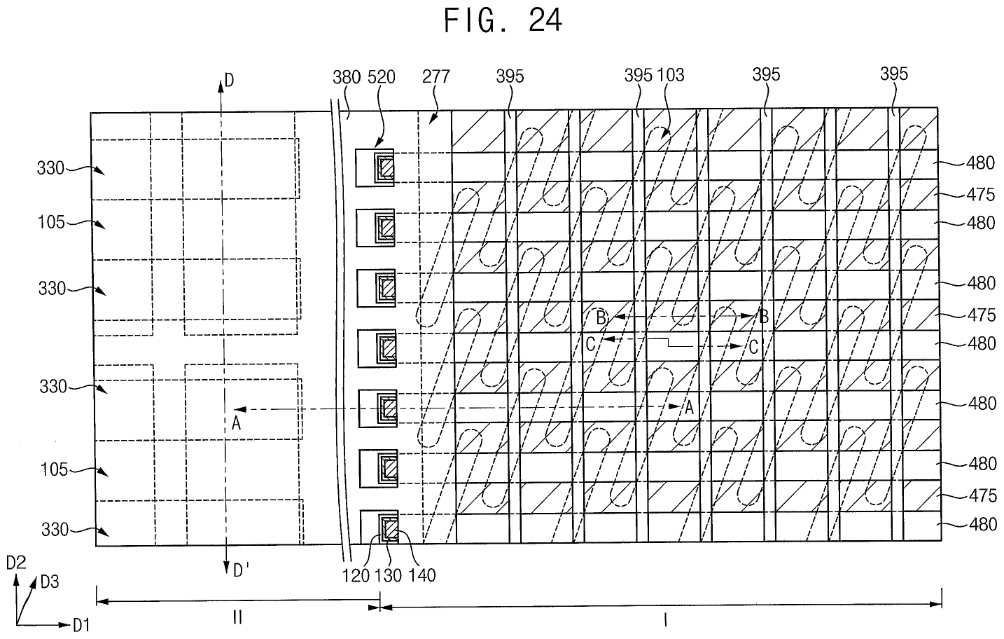

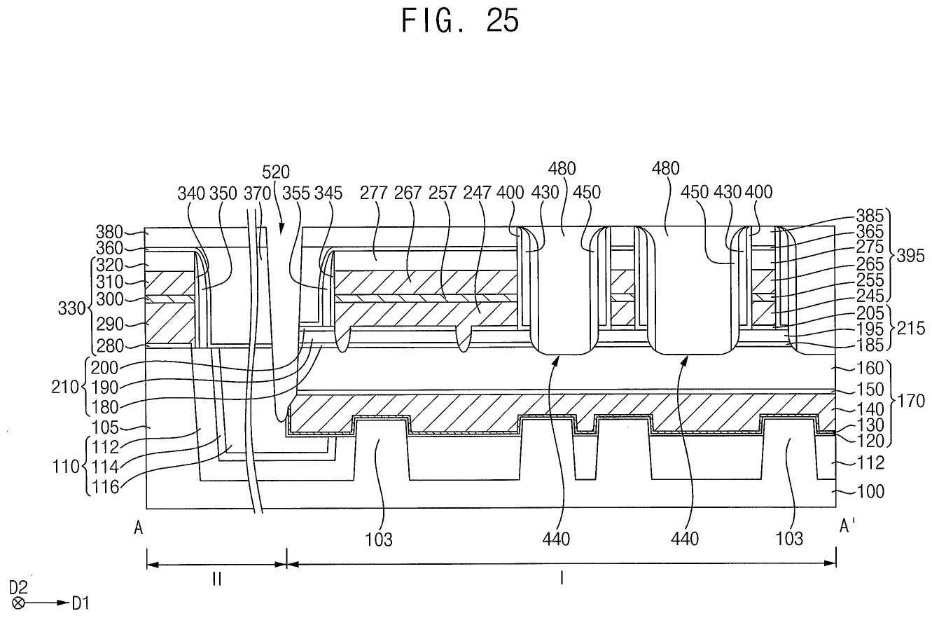

Referring to FIGS. 24 and 25, a first sacrificial layer may be formed on the first and second capping patterns 385 and 480, the eighth spacer 490, the metal silicide pattern 500 and the lower contact plug 475, and an upper portion of the first sacrificial layer may be planarized until upper surfaces of the first and second capping patterns 385 and 480 and the first capping layer 380 are exposed.

In an embodiment, the first sacrificial layer may include SOH, ACL, etc.

A fifth opening 520 may be formed to extend through a portion of the first capping layer 380 on a boundary between the first and second regions I and II of the substrate 100, and the first insulating interlayer 370, the first etch stop layer 360, the insulation layer structure 210, the first gate mask 160, the second conductive pattern 150 and the isolation pattern structure 110 under the portion of the first capping layer 380 to expose the first conductive pattern 140. The fifth opening 520 may also expose the first barrier pattern 130 and the first gate insulation pattern 120 on the sidewall of the first conductive pattern 140.

Additionally, a sixth opening may also be formed to extend through a portion of the first capping layer 380 on the second region II of the substrate 100, and the first insulating interlayer 370 under the portion of the first capping layer 380, and the first etch stop layer 360 to expose an upper surface of the second active pattern 105 between the second gate structures 330. However, the sixth opening may expose an upper surface of the source/drain layer at an upper portion of the second active pattern 105 between the second gate structures 330 serving as a gate of a transistor, and may not be formed between the second gate structures 330 that are dummy gate structures.

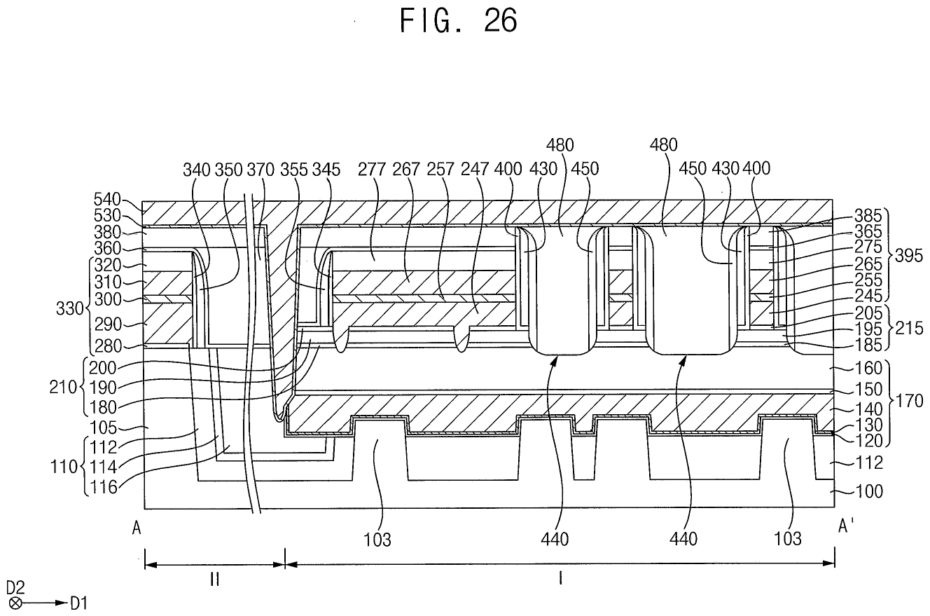

Referring to FIGS. 26 to 28, the first sacrificial layer may be removed, such as by an ashing process and/or a stripping process, and a fifth barrier layer may be formed on the first and second capping patterns 385 and 480, the eighth spacer 490, the metal silicide pattern 500 and the lower contact plug 475 on the first region I of the substrate 100, and the first capping layer 380, a sidewall of the fifth opening 520, and the first conductive pattern 140, the first barrier pattern 130, the first gate insulation pattern 120 and the isolation pattern structure 110 exposed by the fifth opening 520, and the source/drain layer exposed by the sixth opening. A second metal layer 540 may be formed on the fifth barrier layer 530 to fill a space between the bit line structures 395, the fifth opening 520 and the sixth opening.

In an embodiment, the fifth barrier layer 530 may include a metal nitride, such as titanium nitride, tantalum nitride, etc., and the second metal layer 540 may include a metal, such as tungsten.

A planarization process may be further performed on an upper portion of the second metal layer 540. In an embodiment, the planarization process may include a CMP process and/or an etch back process.

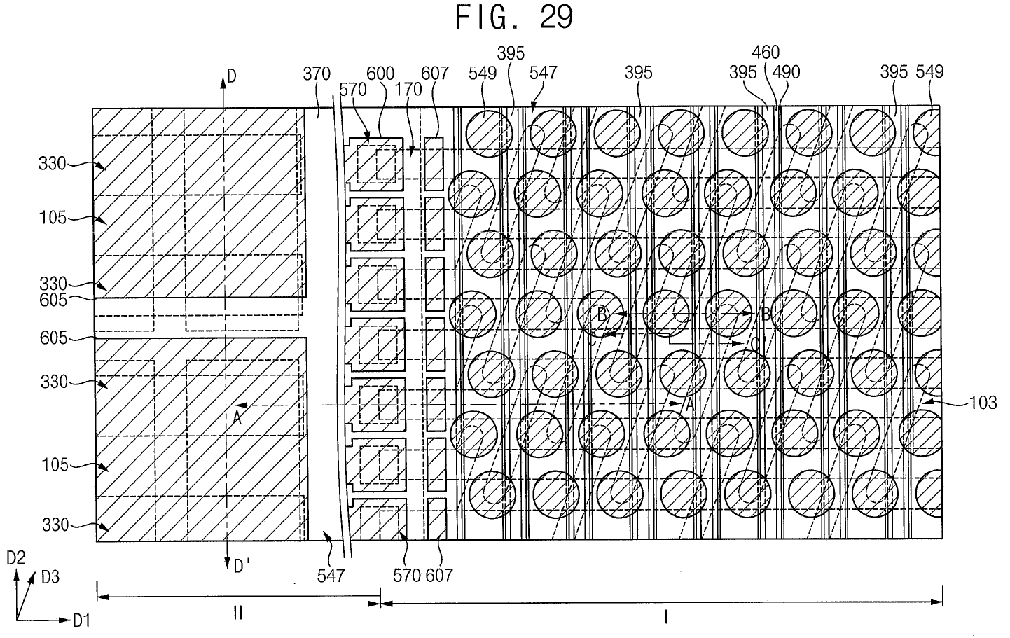

Referring to FIGS. 29 to 32, the second metal layer 540 and the fifth barrier layer 530 may be patterned.

Thus, an upper contact plug 549 may be formed on the first region I of the substrate 100, a first wiring 600 may be formed on the boundary between the first and second regions I and II of the substrate 100, a first conductive pad 605 may be formed on the second region II of the substrate 100, and a second conductive pad 607 may be formed on a portion of the first region I adjacent to the second region II of the substrate 100 in the first direction D1. The first conductive pad 605 may be electrically insulated from the substrate 100. A seventh opening 547 may be formed between the upper contact plug 549, the first wiring 600, and the first and second conductive pads 605 and 607.

The seventh opening 547 may be formed by removing not only the second metal layer 540 and the fifth barrier layer 530 but also the first and second capping patterns 385 and 480, the first capping layer 380, the third spacer structure 460, the eighth spacer 490, the first etch stop layer 360, the first etch stop pattern 365, the first mask 275, the second gate mask 320, and the first and second spacer structures.

As the seventh opening 547 is formed, the second metal layer 540 and the fifth barrier layer may be transformed into a first metal pattern 545 and a fifth barrier pattern 535 covering a lower surface of the first metal pattern 545, which may form an upper contact plug 549. In an embodiment, a plurality of upper contact plugs 549 may be formed to be spaced apart from each other in each of the first and second directions D1 and D2, and may be arranged in a honeycomb pattern or a lattice pattern in a plan view (e.g., in a plane defined in the first and second directions D1, D2). However, embodiments of the present disclosure are not necessarily limited thereto and the shape of the pattern may vary. Each of the upper contact plugs 549 may have a shape of a circle, an ellipse, or a polygon in a plan view. However, embodiments of the present disclosure are not necessarily limited thereto.

The lower contact plug 475, the metal silicide pattern 500 and the upper contact plug 549 sequentially stacked on the first region I of the substrate 100 may form a contact plug structure (herein, referred to as “contact plug structures”).

The first wiring 600 may include a fourth metal pattern 590 and an eighth barrier pattern 580 covering a lower surface of the fourth metal pattern 590, and the first conductive pad 605 may include a fifth metal pattern 595 and a ninth barrier pattern 585 covering a lower surface of the fifth metal pattern 595. A first contact plug 570 including a second metal pattern 560 and a sixth barrier pattern 550 may be formed in the fifth opening 520, and a second contact plug including a third metal pattern and a seventh barrier pattern may be formed in the sixth opening. The second conductive pad 607 may include a sixth metal pattern 597 and a tenth barrier pattern 587 covering a lower surface of the sixth metal pattern 597.

In an embodiment, the first wiring 600 may extend from the boundary between the first and second regions I and II of the substrate 100 toward the second region II of the substrate 100 in the first direction D1, and a plurality of first wirings 600 may be spaced apart from each other in the second direction D2. In an embodiment, the first wiring 600 may overlap the fifth opening 520 in the vertical direction, and at least one of the first wirings 600 may overlap the sixth opening in the vertical direction.

Thus, the first wiring 600 may be connected with the first conductive pattern 140 through the first contact plug 570, and may apply electrical signals to the first gate structure 170. Additionally, the first wiring 600 may be connected with the source/drain layer at the upper portion of the second active pattern 105 through the second contact plug, and may apply electrical signals to the source/drain layer.

In an embodiment, an adjacent two of the first conductive pads 605 on a portion of the second region II of the substrate 100 may form a pair of first conductive pads, and a plurality of pairs of first conductive pads may be spaced apart from each other in each of the first and second directions D1 and D2. One pair of first conductive pads are shown in FIG. 29.

The second conductive pad 607 may overlap the dummy bit line structure in the vertical direction.

In some embodiments, the exposed sixth spacer 430 may be removed to form an air gap connected to the seventh opening 547. For example, in an embodiment the sixth spacer 430 may be removed by, a wet etching process. However, embodiments of the present disclosure are not necessarily limited thereto.

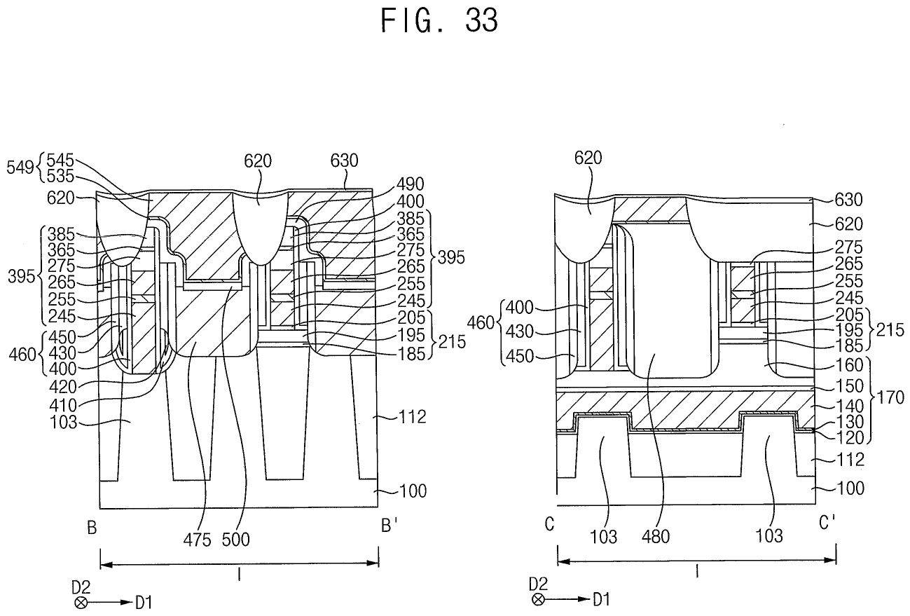

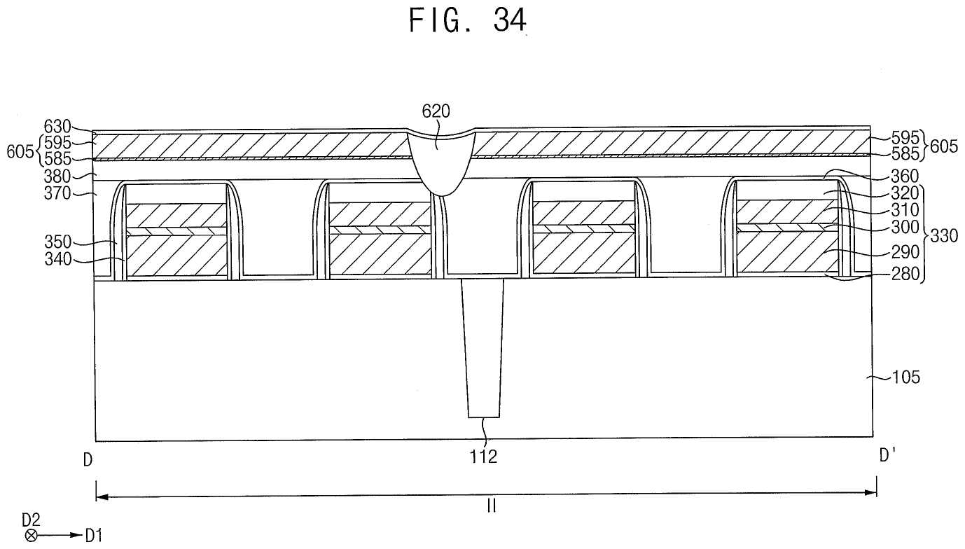

Referring to FIGS. 33 and 34, a sixth insulation layer 620 may be formed to fill the seventh opening 547, and a second etch stop layer 630 may be formed on the sixth insulation layer 620, the upper contact plug 549, the first wiring 600 and the first and second conductive pads 605 and 607.

In an embodiment, the sixth insulation layer 620 may include a nitride, such as a silicon nitride or the like, and the second etch stop layer 630 may include a nitride, such as silicon boronitride, silicon carbonitride, etc.

In an embodiment in which the air gap connected with the seventh opening 547 is formed, the sixth insulation layer 620 may be formed to include a material having a low gap filling characteristic, and thus the air gap may not be filled with the sixth insulation layer 620 but remain.

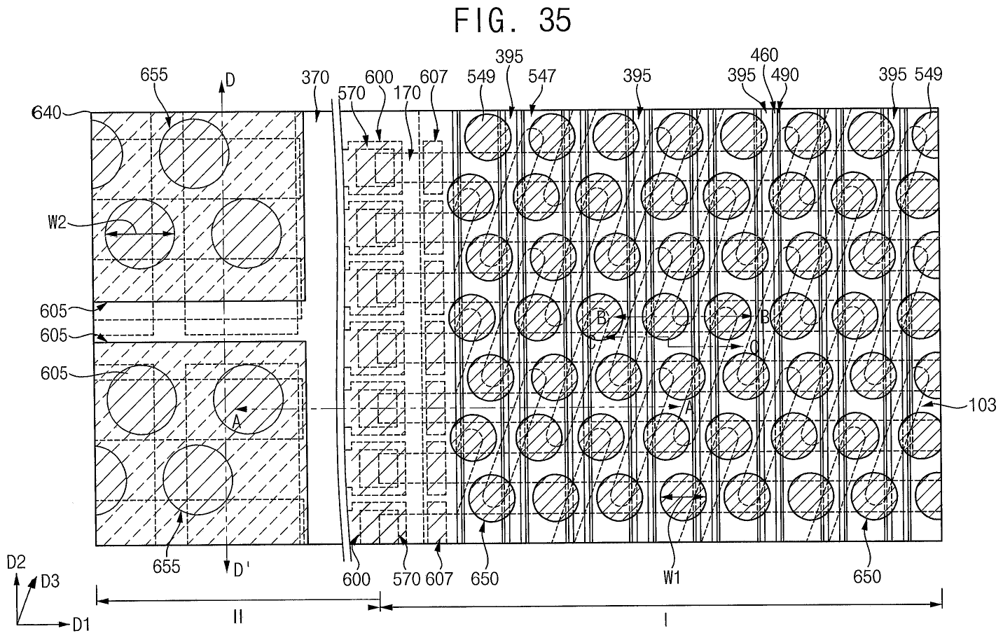

Referring to FIGS. 35 to 38, a mold layer 640 may be formed on the second etch stop layer 630, and a portion of the mold layer 640 and a portion of the second etch stop layer 630 thereunder may be etched to form eighth and ninth openings 650 and 655 partially exposing the upper contact plug 549 and the first conductive pad 605, respectively.

As the plurality of upper contact plugs 549 is spaced apart from each other in each of the first and second directions D1 and D2 in a honeycomb pattern or a lattice pattern in a plan view, a plurality of eighth openings 650 exposing the plurality of upper contact plugs 549, respectively, may be spaced apart from other in each of the first and second directions D1 and D2 in a honeycomb pattern or a lattice pattern in a plan view.

In an embodiment, a plurality of ninth openings 655 may be spaced apart from other on each of the first conductive pads 605 in each of the first and second directions D1 and D2 in a honeycomb pattern or a lattice pattern in a plan view. In an embodiment, each of the ninth openings 655 may have a shape of a circle, an ellipse, a polygon, etc., in a plan view.

In an embodiment, a process of forming the eighth and ninth openings 650 and 655 may be performing by etching the mold layer 640 through an EUV lithography process using extreme ultraviolet (EUV) as an exposure light. Thus, when compared to an ArF lithography process using argon fluoride (ArF) as an exposure light, the eighth and ninth openings 650 and 655 may be formed to have a small size by a single patterning process, not using double patterning technology (DPT).

In a comparative embodiment in which the eighth and ninth openings 650 and 655 having desired small sizes are formed through an ArF lithography process having a relatively low resolution, DPT has to be used instead of a single etching process, and a spacer layer has to be formed by an atomic layer deposition (ALD) process to use a spacer serving as an etching mask. However, the spacer layer may be formed to have a uniform thickness, and forming the spacer layer having different thicknesses at respective different portions is not easy. Thus, if the eighth and ninth openings 650 and 655 are formed on the first and second regions I and II, respectively, of the substrate 100 by the same etching process, the eighth and ninth openings 650 and 655 may have the same size.

As the semiconductor device has been highly integrated, a large number of capacitors are formed on the first region I of the substrate 100, and the eighth opening 650 needs to have a small size to form as many capacitors as possible. Thus, the ninth opening 655 that may be formed by the same process as the eighth opening 650 may also have a small size.

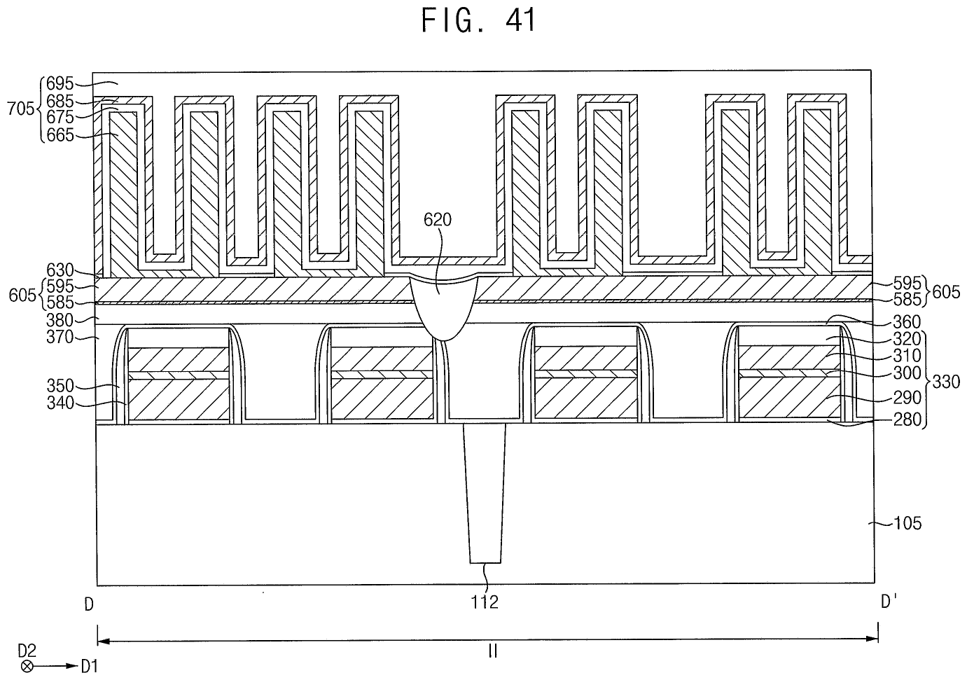

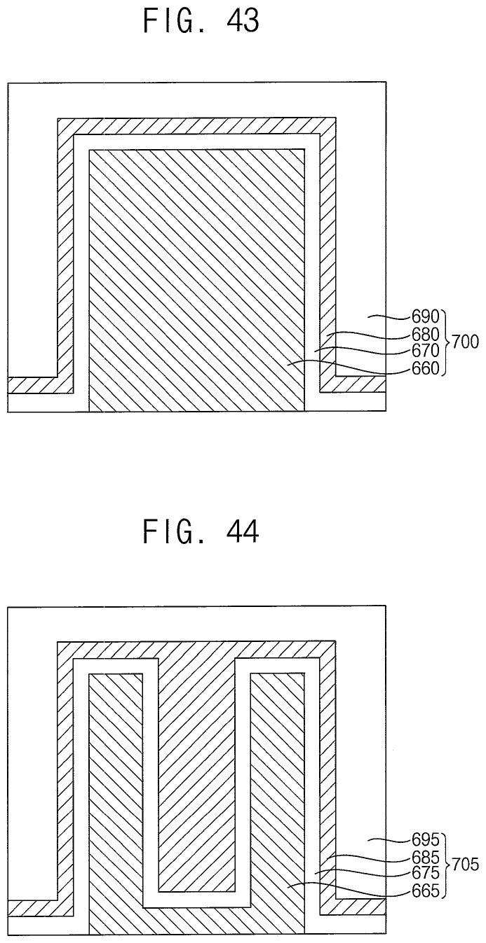

However, if the ninth opening 655 has a small size, a second lower electrode 665 (refer to FIG. 41) in the ninth opening 655 may have a pillar shape (refer to FIG. 43) instead of a hollow cylindrical shape or a cup shape, or a second upper electrode 685 (refer to FIG. 41) may not entirely cover a surface of the second lower electrode 665 having a hollow cylindrical shape or a cup shape. Accordingly, a second capacitor 705 (refer to FIG. 41) including the second lower electrode 665 may have a relatively small electrical capacitance.

However, in an embodiment, the eighth and ninth openings 650 and 655 may be formed by a single etching process for the mold layer 640 through an EUV lithography process having a relatively large resolution, instead of using DPT, and thus, even though the eighth opening 650 has a first width W1, the ninth opening 655 may have a second width W2 greater than the first width W1.

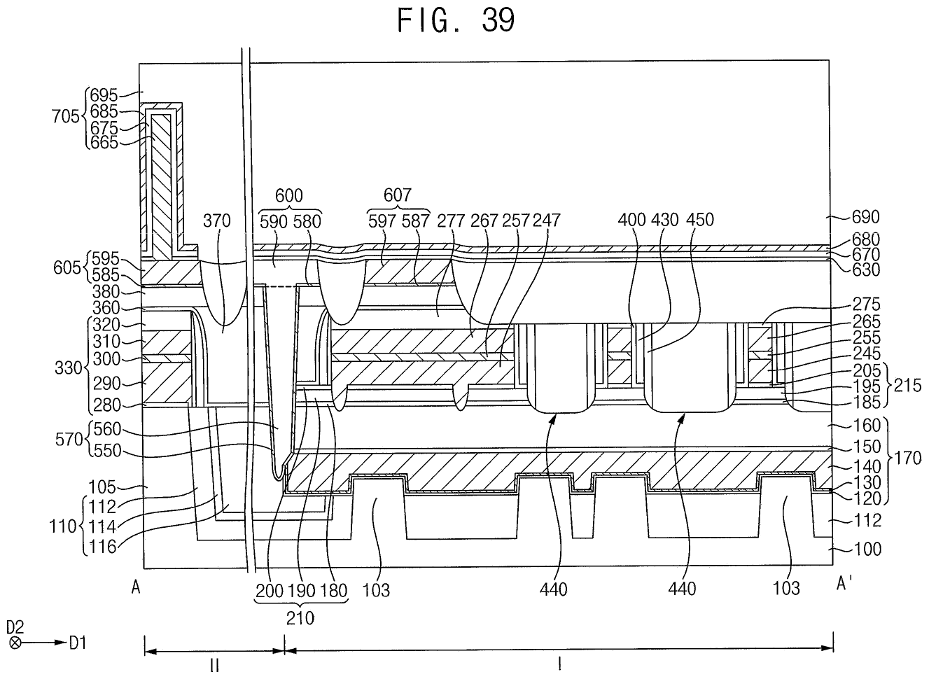

Referring to FIGS. 39 to 41, a lower electrode layer may be formed on sidewalls of the eighth and ninth openings 650 and 655, the exposed upper surfaces of the upper contact plug 549 and the first conductive pad 605, and the mold layer, a second sacrificial layer may be formed on the lower electrode layer to fill the eighth and ninth openings 650 and 655, and the lower electrode layer and the second sacrificial layer may be planarized until an upper surface of the mold layer is exposed to divide the lower electrode layer.

Thus, the first and second lower electrodes 660 and 665 having a cup shape may be formed in the eighth and ninth openings 650 and 655, respectively. In an embodiment, the first and second lower electrodes 660 and 665 may include, a metal, a metal nitride, a metal silicide, doped polysilicon, etc. However, embodiments of the present disclosure are not necessarily limited thereto.

In an embodiment, the second sacrificial layer and the mold layer 640 may be removed by a wet etching process using an etching solution, e.g., LAL.

A dielectric layer may be formed on surfaces of the first and second lower electrodes 660 and 665 and the second etch stop layer 630. In an embodiment, the eighth opening 650 having a relatively small size may be entirely filled with the dielectric layer, and the ninth opening 655 having a relatively large size may not be entirely filled with the dielectric layer. In an embodiment, the dielectric layer may include, a metal oxide. However, embodiments of the present disclosure are not necessarily limited thereto.

A first upper electrode layer may be formed on the dielectric layer, and may not entirely fill the ninth opening 655. For example, the first upper electrode layer may include a first upper electrode 680 formed on the first region I of the substrate 100 and a second upper electrode 685 formed on the second region II of the substrate 100 which may not entirely fill the ninth opening 655. In an embodiment, the first upper electrode layer may include, a metal, a metal nitride, a metal silicide, etc. However, embodiments of the present disclosure are not necessarily limited thereto.

A second upper electrode layer may be formed on the first upper electrode layer, and may fill a remaining portion of the ninth opening 655. For example, the second upper electrode layer may include a third upper electrode 690 formed on the first region I of the substrate 100 and a fourth upper electrode 695 formed on the second region II of the substrate 100 and filling a remaining portion of the ninth opening 655. In an embodiment, the second upper electrode layer may include, silicon-germanium doped with p-type impurities, such as boron. However, embodiments of the present disclosure are not necessarily limited thereto.

The second upper electrode layer may be patterned, and the first upper electrode layer and the dielectric layer may also be patterned to expose the second etch stop layer 630.

Thus, a first capacitor structure including the first lower electrode 660, a first dielectric pattern 670, a first upper electrode 680 and a third upper electrode 690 may be formed on the first region I of the substrate 100, and a plurality of first lower electrodes 660 may be spaced apart from each other, such as in a honeycomb pattern or a lattice pattern in a plan view. Each of the plurality of first lower electrodes 660 and portions of the first dielectric pattern 670, the first upper electrode 680 and the third upper electrode 690 may be referred as a first capacitor 700. Thus, a plurality of first capacitors 700 may be spaced apart from each other in each of the first and second directions D1 and D2 on the first region I of the substrate 100.

Additionally, a second capacitor structure including the second lower electrode 665, a second dielectric pattern 675, a second upper electrode 685 and a fourth upper electrode 695 may be formed on the second region II of the substrate 100, and a plurality of second lower electrodes 665 may be spaced apart from each other, such as in a honeycomb pattern or a lattice pattern in a plan view. Each of the plurality of second lower electrodes 665 and portions of the second dielectric pattern 675, the second upper electrode 685 and the fourth upper electrode 695 may be referred as a second capacitor 705. Thus, a plurality of second capacitors 705 may be arranged to be spaced apart from each other in each of the first and second directions D1 and D2 on the second region II of the substrate 100.

In an embodiment, a plurality of second capacitor structures may be spaced apart from each other on the second region II of the substrate 100. In an embodiment, a plurality of second capacitors 705 may be formed on each of the first conductive pads 605, and the second capacitors 705 on a pair of first conductive pads 605 may share the second dielectric pattern 675, the second upper electrode 685 and the fourth upper electrode 695 (refer to FIG. 42). The second capacitor structure including a plurality of second capacitors 705 on a pair of first conductive pads 605 on the second region II of the substrate 100 may form a decoupling capacitor.

Referring to FIG. 42, a second insulating interlayer 710 may be formed on the first and second capacitor structures on the first and second regions I and II, respectively, of the substrate 100 and the second etch stop layer 630, third and fourth contact plugs 720 and 725 may be formed through the second insulating interlayer 710 to contact upper surfaces of a pair of first conductive pads 605, respectively, and second and third wirings 730 and 735 may be formed to contact upper surfaces of the third and fourth contact plugs 720 and 725, respectively.

In an embodiment, the second insulating interlayer 710 may include an oxide, such as silicon oxide or a low-k dielectric material, and the third and fourth contact plugs 720 and 725 and the second and third wirings 730 and 735 may include a metal, a metal nitride, a metal silicide, etc. However, embodiments of the present disclosure are not necessarily limited thereto.

In an embodiment, a source voltage and a ground voltage may be applied to the second and third wirings 730 and 735, respectively.

Upper insulating interlayers and upper wirings may be formed on the second insulating interlayer 710 and the second and third wirings 730 and 735 so that the semiconductor device may be manufactured.

As illustrated above, an EUV lithography process having a relatively large resolution may be performed on the mold layer 640 so as to form the eighth and ninth openings 650 and 655 for forming the first and second lower electrodes 660 and 665, included in the first and second capacitors 700 and 705, respectively, on the first and second regions I and II of the substrate 100, and thus the eighth and ninth openings 650 and 655 may have different sizes without using DPT.

Thus, only the first lower electrode 660 and the first dielectric pattern 670 may be formed in the eighth opening 650 having a relatively small size, while not only the second lower electrode 665 and the second dielectric pattern 675 but also the second and fourth upper electrodes 685 and 695 may be formed in the ninth opening 655 having a relatively large size. Accordingly, an entire surface of the second lower electrode 665 having a cup shape, except for a bottom surface thereof, may be used in a portion of the capacitor, so that the second capacitor 705 including the second lower electrode 665 may have a large electrical capacitance.

The second capacitor structure including a plurality of second capacitors 705 may receive a source voltage and a ground voltage from the second and third wirings 730 and 735, respectively, electrically connected to the first conductive pads 605 spaced apart from each other, and electric charges may be stored in or emitted from the second capacitor structure so that noises between various circuit patterns on the second region II of the substrate 100 may be removed.

The semiconductor device manufactured by the above processes may have following structural characteristics.

Referring to FIGS. 35 and 39 to 42, the semiconductor device may include the first gate structures 170, each of which may extend in the first direction D1, buried in the cell region I of the substrate 100 which includes the cell region I and the peripheral circuit region II; the bit line structures 395 each of which may extend in the second direction D2 on the cell region I of the substrate 100; the contact plug structures 475, 500 and 549 disposed in the second direction D2 between the bit line structures 395; the first capacitors 700 on the contact plug structures 475, 500 and 549; the first conductive pad 605 on the peripheral circuit region II of the substrate 100 and electrically insulated from the substrate 100; and the second capacitors 705 disposed in the first and second directions D1 and D2 on the first conductive pad 605. Each of the first capacitors 700 may include the first lower electrode 660 having a first cup shape; the first dielectric pattern 670 on the surface of the first lower electrode 660 and filling an inner space of the first cup shape; the first upper electrode 680 on the surface of the first dielectric pattern 670; and the third upper electrode 690 on the surface of the first upper electrode 680. Each of the second capacitors 705 may include the second lower electrode 665 having a second cup shape; the second dielectric pattern 675 on the surface of the second lower electrode 665; the second upper electrode 685 on the surface of the second dielectric pattern 675; and the fourth upper electrode 695 on the surface of the second upper electrode 685. In an embodiment, the second dielectric pattern 675, the second upper electrode 685 and the fourth upper electrode 695 may fill an inner space of the second cup shape.

In an embodiment, a width of the second cup shape may be greater than a width of the first cup shape.

In an embodiment, the first lower electrodes 660 included in the first capacitor 700 may be arranged in a honeycomb pattern or a lattice pattern in a plan view, and the first dielectric pattern 670, the first upper electrode 680 and the third upper electrode 690 included in the first capacitors 700 may be commonly formed on the first lower electrodes 660.

In an embodiment, the second lower electrodes 665 included in the second capacitor 705 may be arranged in a honeycomb pattern or a lattice pattern in a plan view, and the second dielectric pattern 675, the second upper electrode 685 and the fourth upper electrode 695 included in the second capacitors 705 may be commonly formed on the second lower electrodes 665.

In an embodiment, a plurality of first conductive pads 605 may be spaced apart from each other on the peripheral circuit region II of the substrate 100, and the second dielectric pattern 675, the second upper electrode 685 and the fourth upper electrode 695 may be commonly formed on the second lower electrodes 665 on a pair of first conductive pads 605 adjacent to each other among a plurality of first conductive pads 605.

In an embodiment, the second and third wirings 730 and 735 may be formed on and electrically connected to a pair of first conductive pads 605, respectively, and a source voltage and a ground voltage may be applied to the second and third wirings 730 and 735, respectively.

FIGS. 43 and 44 are cross-sectional views illustrating the first and second capacitors 700 and 705 in accordance with embodiments.

Referring to FIG. 43, the first capacitor 700 included in the first capacitor structure may include the first lower electrode 660 having a pillar shape, and may include the first dielectric pattern 670, the first upper electrode 680 and the third upper electrode 690 sequentially stacked on the first lower electrode 660.

For example, when the eighth opening 650 has a small size, the lower electrode layer may entirely fill the eighth opening 650, and thus the first lower electrode 660 may have a pillar shape.

Referring to FIG. 44, the second upper electrode 685 included in the second capacitor structure may fill a remaining portion of the ninth opening 655, and thus the fourth upper electrode 695 may not be formed in the ninth opening 655.

However, at least the second upper electrode 685 may be formed in the ninth opening 655, and an entire surface of the second lower electrode 665 having a cup shape, except for the bottom surface, may be used for the capacitance of the second capacitor 705.

In an embodiment, the first lower electrode 660 included in the first capacitor 700 and the second lower electrode 665 included in the second capacitor 705 may have different sizes, and may have a cup shape or a pillar shape according to the sizes thereof. The dielectric pattern and a portion or an entire portion of the upper electrode may be formed in the first lower electrode 660 or the second lower electrode 665 having the cup shape.

For example, if the first lower electrode 660 has a cup shape, the first dielectric pattern 670 and the first upper electrode 680 may be filled in the inner space of the cup shape of the first lower electrode 660, or the first dielectric pattern 670, the first upper electrode 680 and the third upper electrode 690 may be filled therein. Alternatively, for example, if the second lower electrode 665 has a cup shape, the second dielectric pattern 675 and the second upper electrode 685 may be filled in the inner space of the cup shape of the second lower electrode 665, or the second dielectric pattern 675, the second upper electrode 685 and the fourth upper electrode 695 may be filled therein.

If the first lower electrode 660 and/or the second lower electrode 665 have a cup shape, the dielectric pattern and the upper electrode may not fill the inner space thereof, and a seam may be formed therein.

While the present disclosure has been shown and described with reference to non-limiting embodiments thereof, it will be understood by those of ordinary skill in the art that various changes in form and details may be made thereto without departing from the spirit and scope of the present disclosure.

What is claimed is:

1. A semiconductor device comprising:
a substrate including a cell region and a peripheral circuit region;
gate structures on the cell region of the substrate, each of the gate structures extending in a first direction substantially parallel to an upper surface of the substrate;
bit line structures on the cell region of the substrate, each of the bit line structures extending in a second direction substantially parallel to the upper surface of the substrate and crossing the first direction;
contact plug structures disposed in the second direction between the bit line structures on the substrate;
first capacitors on the contact plug structures, respectively;
a conductive pad on the peripheral circuit region of the substrate, the conductive pad being electrically insulated from the substrate; and
second capacitors on the conductive pad, the second capacitors being arranged in the first and second directions,
wherein:
each of the first capacitors includes:
a first lower electrode having a first cup shape;
a first dielectric pattern on a surface of the first lower electrode, the first dielectric pattern filling an inner space of the first cup shape of the first lower electrode; and
a first upper electrode on a surface of the first dielectric pattern, and
each of the second capacitors includes:
a second lower electrode having a second cup shape;
a second dielectric pattern on a surface of the second lower electrode; and
a second upper electrode on a surface of the second dielectric pattern,
wherein the second dielectric pattern and the second upper electrode fill an inner space of the second cup shape of the second lower electrode.

2. The semiconductor device according to claim 1, wherein a width of the second cup shape of the second lower electrode is greater than a width of the first cup shape of the first lower electrode.

3. The semiconductor device according to claim 1, wherein:
each of the first capacitors further includes a third upper electrode on the first upper electrode; and
each of the second capacitors further includes a fourth upper electrode on the second upper electrode.

4. The semiconductor device according to claim 3, wherein:
each of the first and second upper electrodes includes a metal nitride; and
each of the third and fourth upper electrodes includes silicon-germanium doped with impurities.

5. The semiconductor device according to claim 3, wherein:
the first lower electrodes included in the first capacitors are arranged in a honeycomb pattern or a lattice pattern in a plan view,
wherein the first dielectric pattern, the first upper electrode and the third upper electrode included in the first capacitors are commonly formed on the first lower electrodes.

6. The semiconductor device according to claim 3, wherein:
the second lower electrodes included in the second capacitors are arranged in a honeycomb pattern or a lattice pattern in a plan view,
wherein the second dielectric pattern, the second upper electrode and the fourth upper electrode included in the second capacitors are commonly formed on the second lower electrodes.

7. The semiconductor device according to claim 6, wherein:
the conductive pad includes a plurality of conductive pads spaced apart from each other on the peripheral circuit region of the substrate,
wherein the second dielectric pattern, the second upper electrode and the fourth upper electrode are commonly formed on the second lower electrodes on a pair of conductive pads that are adjacent to each other among the plurality of conductive pads.

8. The semiconductor device according to claim 7, further comprising first and second wirings disposed on and electrically connected to the pair of conductive pads, respectively,
wherein a source voltage and a ground voltage are applied to the first and second wirings, respectively.

9. A semiconductor device comprising:
a substrate including a cell region and a peripheral circuit region;
gate structures on the cell region of the substrate, each of the gate structures extending in a first direction substantially parallel to an upper surface of the substrate in the cell region;
bit line structures on the cell region of the substrate, each of the bit line structures extending in a second direction substantially parallel to the upper surface of the substrate and crossing the first direction;
contact plug structures disposed in the second direction between the bit line structures on the substrate;
first capacitors on the contact plug structures, respectively;
a conductive pad on the peripheral circuit region of the substrate, the conductive pad being electrically insulated from the substrate; and
second capacitors on the conductive pad, the second capacitors being arranged in the first and second directions,
wherein:
each of the first capacitors includes:
a first lower electrode having a first cup shape;
a first dielectric pattern on a surface of the first lower electrode;
a first upper electrode on a surface of the first dielectric pattern; and
a third upper electrode on a surface of the first upper electrode, and
each of the second capacitors includes:
a second lower electrode having a second cup shape;
a second dielectric pattern on a surface of the second lower electrode;
a second upper electrode on a surface of the second dielectric pattern; and
a fourth upper electrode on a surface of the second upper electrode,
wherein the second dielectric pattern, the second upper electrode and the fourth upper electrode fill an inner space of the second cup shape of the second lower electrode.

10. The semiconductor device according to claim 9, wherein a width of the second cup shape of the second lower electrode is greater than a width of the first cup shape of the first lower electrode.

11. The semiconductor device according to claim 9, wherein:
the first lower electrodes included in the first capacitors are arranged in a honeycomb pattern or a lattice pattern in a plan view,
wherein the first dielectric pattern, the first upper electrode and the third upper electrode included in the first capacitors are commonly formed on the first lower electrodes.

12. The semiconductor device according to claim 9, wherein:
the second lower electrodes included in the second capacitors are arranged in a honeycomb pattern or a lattice pattern in a plan view,
wherein the second dielectric pattern, the second upper electrode and the fourth upper electrode included in the second capacitors are commonly formed on the second lower electrodes.

13. The semiconductor device according to claim 12, wherein:
the conductive pad includes a plurality of conductive pads spaced apart from each other on the peripheral circuit region of the substrate,
wherein the second dielectric pattern, the second upper electrode and the fourth upper electrode are commonly formed on the second lower electrodes on a pair of conductive pads that are adjacent to each other among the plurality of conductive pads.

14. The semiconductor device according to claim 13, further comprising first and second wirings disposed on and electrically connected to the pair of conductive pads, respectively,
wherein a source voltage and a ground voltage are applied to the first and second wirings, respectively.

15. A semiconductor device comprising:
a substrate including a cell region and a peripheral circuit region;
gate structures on the cell region of the substrate, each of the gate structures extending in a first direction substantially parallel to an upper surface of the substrate;
bit line structures on the cell region of the substrate, each of the bit line structures extending in a second direction substantially parallel to the upper surface of the substrate and crossing the first direction;
contact plug structures disposed in the second direction between the bit line structures on the substrate;
first capacitors on the contact plug structures, respectively;
a conductive pad on the peripheral circuit region of the substrate, the conductive pad being electrically insulated from the substrate; and
second capacitors on the conductive pad, the second capacitors being arranged in the first and second directions,
wherein:
each of the first capacitors includes:
a first lower electrode having a pillar shape;
a first dielectric pattern on a surface of the first lower electrode;
a first upper electrode on a surface of the first dielectric pattern; and
a third upper electrode on a surface of the first upper electrode,
each of the second capacitors includes:
a second lower electrode having a cup shape;
a second dielectric pattern on a surface of the second lower electrode;
a second upper electrode on a surface of the second dielectric pattern; and
a fourth upper electrode on a surface of the second upper electrode, and
the second dielectric pattern, the second upper electrode and the fourth upper electrode fill an inner space of the cup shape of the second lower electrode.

16. The semiconductor device according to claim 15, further comprising:
active patterns on the substrate, each of the active patterns extending in a third direction substantially parallel to the upper surface of the substrate and having an acute angle with respect to the first and second directions,
wherein each of the bit line structures contacts central upper surfaces in the third direction of corresponding ones of the active patterns, and
each of the contact plug structures contacts an end portion in the third direction of a corresponding one of the active patterns.

17. The semiconductor device according to claim 15, wherein:
the first lower electrodes included in the first capacitors are arranged in a honeycomb pattern or a lattice pattern in a plan view,
wherein the first dielectric pattern, the first upper electrode and the third upper electrode included in the first capacitors are commonly formed on the first lower electrodes.

18. The semiconductor device according to claim 15, wherein:
the second lower electrodes included in the second capacitors are arranged in a honeycomb pattern or a lattice pattern in a plan view,
wherein the second dielectric pattern, the second upper electrode and the fourth upper electrode included in the second capacitors are commonly formed on the second lower electrodes.

19. The semiconductor device according to claim 18, wherein:
the conductive pad includes a plurality of conductive pads spaced apart from each other on the peripheral circuit region of the substrate,
wherein the second dielectric pattern, the second upper electrode and the fourth upper electrode are commonly formed on the second lower electrodes on a pair of conductive pads that are adjacent to each other among the plurality of conductive pads.

20. The semiconductor device according to claim 19, further comprising first and second wirings disposed on and electrically connected to the pair of conductive pads, respectively,
wherein a source voltage and a ground voltage are applied to the first and second wirings, respectively.
